(19) United States
(12) Patent Application Publication
(10) Pub. No.: US 2021/0230191 A1
(43) Pub. Date: Jul. 29, 2021

(54) FORMATION OF METAL-ORGANIC FRAMEWORKS

(71) Applicant: Trustees of Dartmouth College, Hanover, NH (US)

(72) Inventors: Katherine A. Mirica, Hanover, NH (US); Lukasz K. Mendecki, White River Junction, VT (US); Michael KO, West Lebanon, NH (US)

(73) Assignee: Trustees of Dartmouth College, Hanover, NH (US)

(21) Appl. No.: 15/734,789

(22) PCT Filed: Jun. 6, 2019
(86) PCT No.: PCT/US2019/035727

§ 371 Date: Dec. 3, 2020

Related U.S. Application Data
(60) Provisional application No. 62/681,436, filed on Jun. 6, 2018.

(51) Int. Cl. C07F 1/08; C07F 15/06; C07F 15/04; C23C 14/26; C23C 14/18; C23C 14/58

(52) U.S. Cl. CPC C07F 1/08; C07F 15/065; C23C 14/5846; C23C 14/26; C23C 14/18; C07F 15/045

(57) ABSTRACT

In some embodiments, the present disclosure pertains to a method of forming metalorganic frameworks. In some embodiments, the method includes exposing a plurality of zerooxidation state metal atoms to an oxidizing agent. In some embodiments, the exposing facilitates oxidation of the plurality of zero-oxidation state metal atoms to a plurality of metallic ions. In some embodiments, the plurality of metallic ions react with a plurality of ligands to form the metal-organic frameworks. In some embodiments, the formed metal-organic frameworks comprise one or more metals and one or more ligands coordinated with the one or more metals.

### CROSS-REFERENCE TO RELATED APPLICATIONS

This application is a 35 U.S.C. 371 national stage entry of PCT/US2019/035727, filed on Jun. 6, 2019, which claims priority to U.S. Provisional Patent Application No. 62/681,436, filed on Jun. 6, 2018. The entirety of the aforementioned applications is incorporated herein by reference.

### STATEMENT REGARDING FEDERALLY SPONSORED RESEARCH

This invention was made with government support under W911NF-17-1-0398 awarded by the Department of Defense. The government has certain rights in the invention.

### BACKGROUND

Metal-organic frameworks are a class of emerging materials with promising applications in electronics, magnetics, energy storage, electrocatalysis, and chemical sensing. However, current methods of forming metal-organic frameworks have numerous limitations, including multiple fabrication steps. Various embodiments of the present disclosure address the aforementioned limitations.

### SUMMARY

In some embodiments, the present disclosure pertains to methods of forming metal-organic frameworks. In some embodiments, the methods of the present disclosure include exposing a plurality of zero-oxidation state metal atoms to an oxidizing agent. Thereafter, the exposing step facilitates oxidation of the plurality of zero-oxidation state metal atoms to a plurality of metallic ions. The plurality of metallic ions then react with a plurality of ligands to form metal-organic frameworks.

In some embodiments, the methods of the present disclosure also include a step of associating the plurality of zero-oxidation state metal atoms with a surface. In some embodiments, the methods of the present disclosure can also include a step of contacting the plurality of zero-oxidation state metal atoms with the plurality of ligands. In various embodiments, the surface association and ligand contacting steps can occur before, during or after the exposing step.

Additional embodiments of the present disclosure pertain to the formed metal-organic frameworks. The formed metal-organic frameworks include one or more metals and one or more ligands coordinated with the one or more metals.

### DESCRIPTION OF THE DRAWINGS

FIG. 1 illustrates a method of forming metal-organic frameworks (MOFs) according to an embodiment of the present disclosure.

FIG. 2A illustrates an oxidative restructuring synthesis scheme of metal-organic frameworks.

FIG. 2B illustrates deposition of metal on a cotton substrate that is subsequently used as the template for metal-organic framework synthesis.

FIG. 2C illustrates powder X-Ray diffraction spectra for Cu₃HHTP₂ metal-organic frameworks synthesized through oxidative restructuring on cotton.

FIG. 3A illustrates a scanning electron microscopy (SEM) image of Cu₃HHTP₂ metal-organic framework on cotton.

FIG. 3B illustrates an energy-dispersive X-ray spectroscopy (EDS) spectrum of Cu₃HHTP₂ metal-organic framework on cotton with the expected C, O, and Cu elements.

FIG. 3C illustrates an X-ray photoelectron spectroscopy (XPS) spectra obtained for the Cu₃HHTP₂ metal-organic framework on cotton.

FIG. 3D illustrates a high-resolution spectrum in the Cu 2p3 region.

FIG. 3E illustrates a high-resolution spectrum in the O 1s region.

FIGS. 4A and 4B illustrates a stability test of the adhesion of Cu₃HHTP₂ metal-organic framework grown on filter paper. FIG. 4A illustrates a scheme for the stability test run for (1) pristine metal-organic framework, (2) the metal-organic framework after sonication in H₂O, and (3) the metal-organic framework after stirring in sodium dodecyl sulfate (SDS) for 24 hours at 65° C. FIG. 4B illustrates resistance values of the metal-organic framework on the weigh paper after each step.

FIG. 5A illustrates patterned copper (100 nm) deposition on cotton, filter paper, weigh paper, glass slide, mica, and polymethyl methacrylate (PMMA) using a mask to form pre-patterned rectangles of varying dimensions.

FIG. 5B illustrates copper on substrates that have undergone oxidative restructuring to form Cu₃HHTP₂.

FIG. 6A illustrates cyclic voltammetry of Cu₃HHTP₂ with a Ru(NH₃)₆Cl₃ redox probe. Experimental conditions: 0.1 M KCl containing 1 mM of Ru(NH₃)₆Cl₃ under nitrogen atmosphere. Scan rate: 10 mV/sec.

FIG. 6B illustrates differential pulse voltammetry of Cu₃HHTP₂ with dopamine and nitric oxide. Experimental conditions: 0.1 M PBS buffer (pH=7.4) under nitrogen, 50 mV/sec; DA 10⁻⁵; NO delivered through a balloon approximately 500 mL total. Ag/AgCl and platinum wire were used as reference and counter electrodes, respectively.

FIG. 6C illustrates electrochemical impedance of Cu₃HHTP₂ with NO. Experimental conditions: 0.1 M PBS buffer (pH=7.4) under nitrogen. 10 mV amplitude, 100 kHz-0.1 Hz; NO delivered through a balloon filled with approximately 500 mL total.

FIG. 6D illustrates amperometry of Cu₃HHTP₂ with NO. Experimental conditions: 0.1 M PBS buffer (pH=7.4) under nitrogen; +0.5 V; NO delivered through a balloon filled with approximately 500 mL total.

FIG. 6E illustrates chemiresistive sensing using Cu₃HHTP₂ detecting NO. Experimental conditions: NO diluted in air to 80 ppm was delivered to an enclosure containing the Cu₃HHTP₂ grown on cotton.

FIG. 6F illustrates chemiresistive sensing using Cu₃HHTP₂ detecting H₂S. Experimental conditions: H₂S diluted in air to 80 ppm was delivered to an enclosure containing the Cu₃HHTP₂ grown on cotton.

FIGS. 7A, 7B, and 7C illustrates synthetic requirements and proposed mechanism for oxidative restructuring. FIG. 7A illustrates requirements for MOF synthesis which include the hexatopic organic ligand, 1:1 H₂O:EtOH, zero-valent copper, oxygen, and ambient temperature.

FIG. 7B illustrates oxidative restructuring forms MOFs on solid supports demonstrated on cotton. Copper (120 nm) is evaporated on to both sides of the cotton swatch. FIG. 7C illustrates oxidative restructuring occurs when both the metal and organic ligand get oxidized by oxygen and subsequently the oxidized products react leading to the templating of MOF on the substrate.

FIG. 8 illustrates particle PXRD.

FIG. 9 illustrates SEM images of Cu₃HHTP₂ and Cu (45 μm) powder.

FIGS. 10A and 10B illustrates characterization of MOF on cotton. FIG. 10A illustrates scanning electron micrographs showing nanoscale morphology of Cu₃HHTP₂ MOFs on cotton.

FIG. 10B illustrates characterization of Cu₃HHTP₂ on cotton using PXRD. The formation of MOF is observed with the appearance of the (100) plane and disappearance of (111) copper diffraction plane.

FIG. 11 illustrates SEM images of CuHHTP on cotton.

FIG. 12A illustrates surface analysis on Cu₃HHTP₂ on cotton using XPS.

FIG. 12B illustrates a spectrum in the Cu 2p3 region.

FIG. 12C illustrates a spectrum in the O 1s region.

FIG. 13 illustrates Brunauer-Emmett-Teller (BET) analysis for Cu₃HHTP₂ on cotton.

FIGS. 14A and 14B illustrates substrate scope. FIG. 14A illustrates scanning electron micrographs showing nanoscale morphology of Cu₃HHTP₂ MOFs on different substrates at magnifications of 1,000×, 5,000×, and 25,000×. FIG. 14B illustrates stability test using resistance as a measure of MOF adherence on the various solid supports. The stability test includes sonication in H₂O for one hour followed by simulated washing conditions which includes stirring in 0.05 M SDS at 65 C for 24 hours.

FIGS. 15A, 15B and 15C illustrates sensing performance of Cu₃HHTP₂ on cotton as chemiresistors when exposed to gaseous analytes. Representative sensing traces show the change in conductance −ΔG/G₀ (%) over time (min) when exposed to three different gases (FIG. 15A) NH₃, (FIG. 15B) NO, and (FIG. 15C) H₂S ranging from 5-80 ppm diluted with N₂ at room temperature. The grey region represents the duration of exposure to the analyte and the white region represents baseline and recovery in N₂. Also shown are concentration dependence plots of sensing response of the Cu₃HHTP₂ MOF on cotton to NH₃, NO and H₂S (5-80 ppm).

FIG. 16A illustrates cyclic voltammetry of Cu₃HHTP₂ with a Ru(NH₃)₆Cl₃ redox probe. Experimental conditions: 0.1 M KCl containing 1 mM of Ru(NH₃)₆Cl₃ under nitrogen atmosphere. Scan rate: 10 mV/sec.

FIG. 16B illustrates differential pulse voltammetry of Cu₃HHTP₂ with dopamine and nitric oxide. Experimental conditions: 0.1 M PBS buffer (pH=7.4) under nitrogen, 50 mV/sec; DA 10⁻⁵; NO delivered through a balloon approximately 500 mL total. Ag/AgCl and platinum wire were used as reference and counter electrodes, respectively.

FIG. 16C illustrates electrochemical impedance of Cu₃HHTP₂ with NO. Experimental conditions: 0.1 M PBS buffer (pH=7.4) under nitrogen. 10 mV amplitude, 100 kHz-0.1 Hz; NO delivered through a balloon filled with approximately 500 mL total.

FIGS. 17A and 17B illustrates representative sensing traces showing the change in conductance −ΔG/G₀ (%) over time (min) when exposed to two different gasses: H₂S (FIG. 17A) and NO (FIG. 17B) ranging from 5-80 ppm diluted with N₂ at room temperature. The grey region represents the duration of exposure to the analyte and the white region represents baseline and recovery in N₂. Concentration dependence plots of sensing response of the Cu₃HHTP₂ MOF on cotton to H₂S and NO (5-80 ppm) reveal a linear response from 5-20 ppm for H₂S with saturation occurring after 20 ppm whereas NO has a linear response from 5-40 ppm and a saturation event after 40 ppm. The initial rates of response at each specific concentration show a stronger linear response compared to the overall change in response.

FIG. 18 illustrates a powder x-ray diffraction (PXRD) of CoHHTP.

FIG. 19 illustrates patterned copper (120 nm) deposition on cotton, filter paper, weigh paper, nylon, polyester, and silk using a mask to form pre-patterned rectangles of varying dimensions (1 cm×0.5 cm, and 1 cm×0.4 cm) followed by oxidative restructuring to form Cu₃HHTP₂.

FIG. 20 illustrates SEM images of Cu and Cu₃HHTP₂ on substrates.

FIGS. 21A and 21B illustrates SEM images of Cu on cotton (FIG. 21A) and CuHHTP on cotton (FIG. 21B).

FIGS. 22A and 22B illustrates SEM images of CuHHTP on cotton after washing (FIG. 22A) and sonification (FIG. 22B).

FIGS. 23A and 23B illustrates SEM images of Cu on weighpaper (FIG. 23A) and CuHHTP on weighpaper (FIG. 23B).

FIGS. 24A and 24B illustrates SEM images of CuHHTP on weighpaper after washing (FIG. 24A) and sonification (FIG. 24B).

FIGS. 25A and 25B illustrates SEM images of Cu on nylon (FIG. 25A) and CuHHTP on nylon (FIG. 25B).

FIGS. 26A and 26B illustrates SEM images of CuHHTP on nylon after washing (FIG. 26A) and sonification (FIG. 26B).

FIGS. 27A and 27B illustrates SEM images of Cu on polyester (FIG. 27A) and CuHHTP on polyester (FIG. 27B).

FIGS. 28A and 28B illustrates SEM images of CuHHTP on polyester after washing (FIG. 28A) and sonification (FIG. 28B).

FIGS. 29A and 29B illustrates SEM images of Cu on silk (FIG. 29A) and CuHHTP on silk (FIG. 29B).

FIGS. 30A and 30B illustrates SEM images of CuHHTP on silk after washing (FIG. 30A) and sonification (FIG. 30B).

FIGS. 31A, 31B, and 31C illustrates sensing performance of Cu₃HHTP₂ on cotton as chemoreceptors when exposed to gaseous analytes. Representative sensing traces show the change in conductance −ΔG/G₀ (%) over time (min) when exposed to three different gasses: NH₃ (FIG. 31A), NO (FIG. 31B), and H₂S (FIG. 21C) ranging from 5-80 ppm diluted with N₂ at room temperature. The grey region represents the duration of exposure to the analyte and the white region represents baseline and recovery in N₂. Also shown are concentration dependence plots of sensing response of the Cu₃HHTP₂ MOF on cotton to NH₃, NO, and H₂S (5-80 ppm).

FIG. 32 illustrates reusability of washed devices for chemiresistive sensing.

### DETAILED DESCRIPTION

It is to be understood that both the foregoing general description and the following detailed description are illustrative and explanatory, and are not restrictive of the subject matter, as claimed. In this application, the use of the singular includes the plural, the word “a” or “an” means “at least one”, and the use of “or” means “and/or”, unless specifically stated otherwise. Furthermore, the use of the term “including”, as well as other forms, such as “includes” and “included”, is not limiting. Also, terms such as “element” or “component” encompass both elements or components comprising one unit and elements or components that include more than one unit unless specifically stated otherwise.

The section headings used herein are for organizational purposes and are not to be construed as limiting the subject matter described. All documents, or portions of documents, cited in this application, including, but not limited to, patents, patent applications, articles, books, and treatises, are hereby expressly incorporated herein by reference in their entirety for any purpose. In the event that one or more of the incorporated literature and similar materials defines a term in a manner that contradicts the definition of that term in this application, this application controls.

Two-dimensional conductive metal-organic frameworks are a class of emerging materials with promising applications in electronics, magnetics, energy storage, electrocatalysis, and chemical sensing. Nonetheless, the design strategies for developing customizable and stable metal-organic frameworks are limited in scope.

Typically, metal-organic framework synthesis involves solution based solvothermal reactions which enable a high degree of controlled synthesis through bottom-up self-assembly. Recently however, a more efficient method for precise control over the growth of metal-organic frameworks has been developed through a three-step process.

The three-step process includes: (1) the precise deposition of Cu(0); (2) the conversion of Cu (0) to Cu(OH)₂; and (3) conversion to Cu₃(1,3,5-benzenetricarboxylic acid)₂ (Cu₃(BTC)₂). The dual function of the solid metal is utilized as the nucleation site and the source of the metal for the metal-organic framework growth. The advantages of this method include i) a green method of metal-organic framework synthesis limiting the anionic waste, and ii) precise control over the growth of multifunctional materials.

However, the current method of forming metal-organic frameworks (MOFs) using zero-valent metal substrates have three limitations. First, the MOFs formed are all three-dimensional MOFs that have low or no conductivity, thereby limiting their applications in electronic-based devices. Second, the formation of MOFs is through a two-step process that involves the metal oxide intermediate. Third, the use of metal oxides as the metal source may lead to slower MOF growth kinetics due to the high lattice energies of metal oxides, thereby leading to the slow dissolution of metal ions from the metal oxide.

As such, a need exists for more effective methods for forming metal-organic frameworks. Various embodiments of the present disclosure address the aforementioned need.

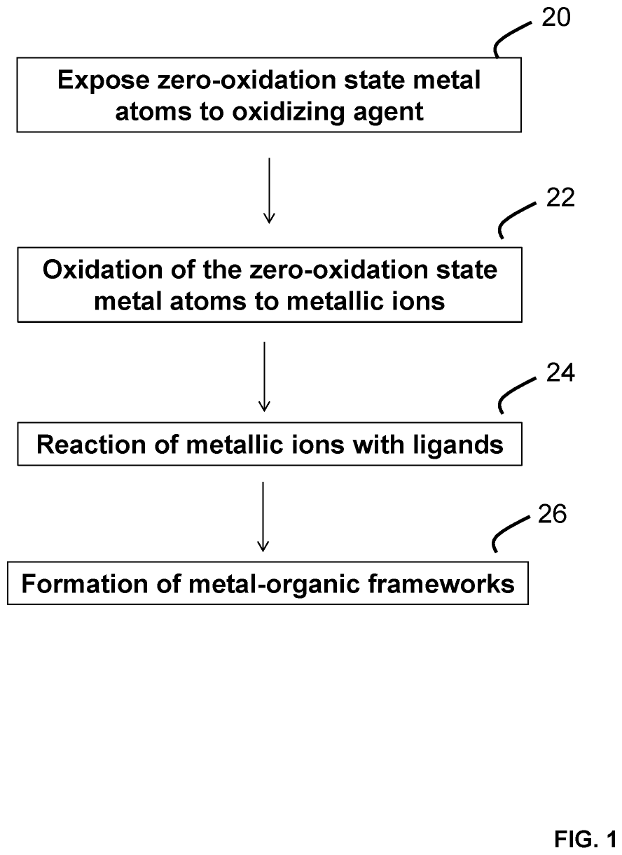

In some embodiments, the present disclosure pertains to methods of forming metal-organic frameworks. In some embodiments illustrated in FIG. 1, the methods of the present disclosure include a step of exposing a plurality of zero-oxidation state metal atoms to an oxidizing agent (20) to facilitate their oxidation to a plurality of metallic ions (step 22). Subsequently, the metallic ions react with a plurality of ligands (step 24) to form metal-organic frameworks (step 26). The formed metal-organic frameworks include one or more metals and one or more ligands coordinated with the one or more metals.

In some embodiments, the methods of the present disclosure also include a step of associating the plurality of zero-oxidation state metal atoms with a surface. In various embodiments, the associating can occur before, during or after the exposing step. In some embodiments, the methods of the present disclosure can also include a step of contacting the plurality of zero-oxidation state metal atoms with the plurality of ligands. In various embodiments, the contacting step can occur before, during or after the exposing step.

As set forth in more detail herein, the methods of the present disclosure can have numerous embodiments. For instance, the methods of the present disclosure can utilize various zero-oxidation state metal atoms, oxidizing agents, metallic ions, and ligands to form various types of metal-organic frameworks. Moreover, in some embodiments, various methods may be utilized to associate zero-oxidation state metal atoms with various surfaces. In some embodiments, various methods may also be utilized to contact zero-oxidation state metal atoms with ligands.

Zero-Oxidation State Metal Atoms

Zero-oxidation state metal atoms generally refer to metal atoms that have a valency of zero. The methods of the present disclosure can utilize various types of zero-oxidation state metal atoms. For instance, in some embodiments, the zero-oxidation state metal atoms can include, without limitation, a metal, a metalloid, a transition metal, a post-transition metal, a lanthanide, or combinations thereof. In more specific embodiments, the zero-oxidation state metal atoms can include, without limitation, copper, cobalt, nickel, zinc, silver, iron, zirconium, scandium, or combinations thereof. In some embodiments, the zero-oxidation state metal atoms can include copper. In some embodiments, the zero-oxidation state metal atoms can include cobalt.

Oxidizing Agents

The methods of the present disclosure can utilize various types of oxidizing agents. For instance, in some embodiments, the oxidizing agents can include, without limitation, an oxygen-containing compound, O₂, H₂O₂, a halogen, atmospheric oxygen (O₂), or combinations thereof. In some embodiments, the oxidizing agents include atmospheric oxygen.

Exposing Zero-Oxidation State Metal Atoms to an Oxidizing Agent

Various methods may be utilized to expose zero-oxidation state metal atoms to oxidizing agents. For instance, in some embodiments, the exposing is performed, without limitation, by at least one of mixing, dipping, spraying, spin coating, thermal evaporation, vapor deposition, painting, drop casting, electroplating, electro-less plating, and combinations thereof.

The exposing step can occur for various periods of time. For instance, in some embodiments, the exposing is performed for a period of time sufficient for at least some of the zero-oxidation state metal atoms to undergo oxidation. In some embodiments, the exposing is performed for a period of time sufficient for a majority of the zero-oxidation state metal atoms to undergo oxidation. In some embodiments, the exposing is performed for a period of time sufficient for substantially all of the zero-oxidation state metal atoms to undergo oxidation. In some embodiments, the exposing is performed for a period of time sufficient for each of the zero-oxidation state metal atoms to undergo oxidation.

In some embodiments, the exposing is performed for about 15 minutes to about 240 minutes. In some embodiments, the exposing is performed for about 45 minutes to about 120 minutes. In some embodiments, the exposing is performed for about 60 seconds. In some embodiments, the exposing is performed for about 60 minutes.

The exposing step can have various effects. For instance, in some embodiments, the exposing step facilitates oxidation of zero-oxidation state metal atoms to metallic ions, as disclosed herein. In some embodiments, the plurality of zero-oxidation state metal atoms undergo oxidation and provide nucleation sites for growth of the metal-organic frameworks. In some embodiments, the exposing step results in slipped parallel packing of the metal-organic frameworks. In some embodiments, the exposing step results in oxidative restructuring.

In some embodiments, the exposing step facilitates the in situ formation of metallic ions. In some embodiments, the in situ formation occurs by an oxidation method that can include, but is not limited to, air oxidation, steam oxidation, water oxidation, salt bath oxidation, or combinations thereof. In some embodiments, the in situ formation occurs by an oxidation method that includes air oxidation.

Metallic Ions

The methods of the present disclosure can form various types of metallic ions. For instance, in some embodiments, the metallic ions can include, without limitation, Co²⁺, Ni²⁺, Cu²⁺, Cu⁺, Ag⁺, Fe²⁺, Zn²⁺, Zr⁺, Zr²⁺, Sc⁺, or combinations thereof. In particular embodiments, the metallic ions include, without limitation, Co²⁺, Cu²⁺, Cu⁺, or combinations thereof. In some embodiments, the metallic ions exclude metal oxides. In some embodiments, the metallic ions exclude metal hydroxides. In some embodiments, the metallic ions exclude metal oxide intermediates. In some embodiments, the metallic ions exclude metal hydroxide intermediates.

Ligands

The methods of the present disclosure can also utilize various types of ligands. For instance, in some embodiments, the ligands can include, without limitation, organic ligands, amino acids, dipeptide linkers, glycine-serine dipeptide linkers, beta-alanine and L-histidine dipeptide linkers, 4,4′-bipyridine linkers, polydentate linkers, bidentate linkers, tridentate linkers, imidazole linkers, hexatopic ligands, polydentate functional groups, aromatic ligands, triphenylene-based ligands, triphenylene derivatives, hexahydroxytriphenylene-based organic linkers, hexaiminotriphenlyene-based organic linkers, tridentate ligands, thiol-containing ligands, tridentate thiol-containing ligand, bis(dithiolene), or combinations thereof.

In some embodiments, the ligands can include, without limitation, 2,3,6,7,10,11-hexahydroxytriphenylene (HHTP), 2,3,6,7,10,11-hexaaminotriphenylene (HITP), trimesic acid (1,3,5-benzenetricarboxylic acid, BTC), aspartic acid, 2,3,6,7,10,11-hexathiotriphenylene (HTTP), terephthalic acid (1,4-benzodicarboxylic acid), 4,4′-biphenyldicarboxylate (BPDC), p-terphenyl-4,4′-dicarboxylate, 1,3,5-tris (3′,5′-dicarboxy[1,1′-biphenyl]-4-yl)benzene, dppd(1,3-di(4-pyridyl)propane-1,3-dionato), 1,3,5-Tris(4-carboxyphenyl)benzene (BTB), or combinations thereof. In particular embodiments, the ligands include, without limitation, HHTP, HITP, or BTC.

Contacting Zero-Oxidation State Metal Atoms with a Plurality of Ligands

In some embodiments, the methods of the present disclosure also include a step of contacting zero-oxidation state metal atoms with ligands. The contacting step can occur at various times. For instance, in some embodiments, the contacting step occurs before the exposing step. In some embodiments, the contacting step occurs after the exposing step. In some embodiments, the contacting step occurs during the exposing step.

The contacting step can occur in various manners. For instance, in some embodiments, the contacting step can occur by mixing zero-oxidation state metal atoms with ligands. In some embodiments, the mixing occurs in a solution or suspension. In some embodiments, the contacting step can occur by incubating zero-oxidation state metal atoms with ligands.

Associating Zero-Oxidation State Metal Atoms with a Surface

In some embodiments, the methods of the present disclosure also include a step of associating zero-oxidation state metal atoms with a surface. In some embodiments, the associating is performed, without limitation, by at least one of mixing, dipping, spraying, spin coating, thermal evaporation, vapor deposition, painting, drop casting, electroplating, electro-less plating, patterning, or combinations thereof.

In some embodiments, the associating occurs by patterning. In some embodiments, the patterning forms a geometric pattern of the zero-oxidation state metal atoms on the surface. In some embodiments, the geometric pattern can include, without limitation, polygons, triangles, squares, rectangles, pentagons, ridges, protrusions, or combinations thereof.

In some embodiments, the patterning step and the exposing step result in the patterned growth of the metal-organic frameworks on the surface. In some embodiments, the growth forms an oriented and continuous coating on the surface.

In some embodiments, the plurality of zero-oxidation state metal atoms patterned on the surface enhance the roughness of the surface. In some embodiments, the higher surface roughness facilitates stable adhesion of the metal-organic frameworks onto the surface.

The zero-oxidation state metal atoms of the present disclosure can become associated with various surfaces. For instance, in some embodiments, the surface can include, without limitation, textiles, cotton, nylon, glass, functionalized glass, paper, silica, mica, natural polymers, synthetic polymers, non-crystalline amorphous solids, carbon-based materials, carbon fibers, porous materials, flexible materials, or combinations thereof. In some embodiments, the surface is glass.

In some embodiments, the surface is functionalized with a functional group to provide an anchor for the plurality of metallic ions formed by the plurality of zero-oxidation state metal atoms. In some embodiments, the functional group is a hydroxyl group. In some embodiments, the surface is in the form of a substrate. In some embodiments, the surface is flexible.

The associating step can occur at various times. For instance, in some embodiments, the associating step occurs before the exposing step. In some embodiments, the associating step occurs during the exposing step. In some embodiments, the associating step occurs after the exposing step.

The association step can have various effects. For instance, in some embodiments, the plurality of zero-oxidation state metal atoms become present in the form of the surface. In some embodiments, the plurality of zero-oxidation state metal atoms become present in the form of particles or solids on the surface. In some embodiments, the plurality of zero-oxidation state metal atoms become part of the surface. In some embodiments, the plurality of zero-oxidation state metal atoms become embedded in the surface.

In some embodiments, the plurality of zero-oxidation state metal atoms form a layer on the surface. In some embodiments, the formed layer has a thickness of about 100 nm. In some embodiments, the formed layer has a thickness ranging from about 100 nm to about 1 μm.

Metal-Organic Frameworks

Additional embodiments of the present disclosure pertain to metal-organic frameworks formed by the methods of the present disclosure. The metal-organic frameworks of the present disclosure generally include one or more metals coordinated with one or more ligands.

The metal-organic frameworks of the present disclosure can include various types of metals. For instance, in some embodiments, the one or more metals can be one or more of the zero-oxidation state metal atoms as disclosed herein, one more of the plurality of metallic ions as disclosed herein, or combinations thereof. In some embodiments, the one or more metals can include, without limitation, monovalent metals, divalent metals, trivalent metals, or combinations thereof.

The metal-organic frameworks of the present disclosure may be in various forms. For instance, in some embodiments, more than one type of metal may be used within the same metal-organic frameworks. In some embodiments, the one or more metals of the metal-organic frameworks may be in the form of at least one of metal ions, metal clusters, metallic nodes, metal catecholates, metal salts, or combinations thereof.

In some embodiments, the one or more metals can include, without limitation, cobalt (II), nickel (II), copper (II), copper (I), silver (I), iron (II), zinc (II), zirconium (II), scandium (I), or combinations thereof.

The metal-organic frameworks of the present disclosure can include various types of ligands. For instance, in some embodiments, the ligands can be one or more of the ligands as disclosed herein. For example, in some embodiments, the one or more ligands are HHTP, HITP, or BTC.

In some embodiments, the metal-organic frameworks can include, without limitation, Co₃HTTP₂, Ni₃HTTP₂, Cu₃HTTP₂, Co₃HHTP₂, Ni₃HHTP₂, Cu₃HHTP₂, Co₃HITP₂, Ni₃HITP₂, Cu₃HITP₂, CuBTC, or combinations thereof. In some embodiments, the metal-organic frameworks are two-dimensional. In some embodiments, the metal-organic frameworks are three-dimensional. In some embodiments, the metal-organic frameworks are conductive.

The metal-organic frameworks of the present disclosure can have various structures. For instance, in some embodiments, the metal-organic frameworks of the present disclosure are in the form of rods, such as nanorods.

The metal-organic frameworks of the present disclosure can also be associated with various surfaces in various manners. For instance, in some embodiments, the metal-organic frameworks of the present disclosure become present in the form of the surface. In some embodiments, the metal-organic frameworks of the present disclosure become present in the form of particles or solids on the surface. In some embodiments, the metal-organic frameworks of the present disclosure become part of the surface. In some embodiments, the metal-organic frameworks of the present disclosure become embedded in the surface.

In some embodiments, the metal-organic frameworks of the present disclosure form a layer on the surface. In some embodiments, the formed layer has a thickness of about 100 nm. In some embodiments, the formed layer has a thickness ranging from about 100 nm to about 1 μm.

In some embodiments, the metal-organic frameworks of the present disclosure are in the form of a continuous coating on a surface. In some embodiments where the surface is a textile (e.g., a cotton substrate), the metal-organic frameworks of the present disclosure are coated around the circumference of individual textile fibers.

Applications and Advantages

The methods of the present disclosure provide numerous advantages. First, the methods presented herein proceed in a similar synthetic route of using a zero-oxidation state metal, but without the need to convert the zero-oxidation state metal into a metal oxide intermediate. Second, the methods presented herein can synthesize two-dimensional conductive metal-organic frameworks, thereby expanding the scope of the methods and extending their application into electronic based materials. Third, the templating of the metal and the growth of metal-organic frameworks, as disclosed herein, can occur not only on sturdy surfaces but also on flexible substrates.

Moreover, the methods of the present disclosure provide for the formation of metal-organic frameworks on a variety of metal pre-patterned substrates. In some embodiments, the metal-organic frameworks formed by the methods herein can be expanded to other two-dimensional or three-dimensional metal-organic frameworks based on other metal centers.

Additionally, the methods of forming metal-organic frameworks on substrates, as disclosed herein, demonstrate optimal mechanical stability to both chemical and mechanical treatment without a significant loss of conductivity. In some embodiments, for example, when the substrate is cotton, the conductivity of the metal-organic framework coated cotton is unaltered if exposed to mechanical stress such as, but not limited to, pulling or stretching, indicating optimal robustness of the developed material.

As such, the metal-organic frameworks formed by the methods of the present disclosure can be utilized in various manners and for various purposes. For instance, in some embodiments, the formed metal-organic frameworks can be utilized as sensors to detect analytes. In some embodiments, the analytes can include, without limitation, nitric oxide (NO), dopamine (DA), hydrogen sulfide (H₂S), or combinations thereof. In some embodiments, the metal-organic framework sensors can be incorporated into, or grown on, fabrics, such as cotton and wearable electronics.

In some embodiments, the metal-organic frameworks formed by the methods disclosed herein can be utilized as both an electrical conductor and sensing element/transducer in voltammetric measurements. In some embodiments, the metal-organic frameworks formed by the methods disclosed herein can be utilized to differentiate between DA and NO. In some embodiments, metal-organic frameworks grown on a surface (e.g., cotton), as disclosed herein, can be utilized to successfully detect NO through electrochemical impedance spectroscopy (EIS) measurements and amperometric sensing.

### Additional Embodiments

Reference will now be made to more specific embodiments of the present disclosure and experimental results that provide support for such embodiments. However, Applicants note that the disclosure below is for illustrative purposes only and is not intended to limit the scope of the claimed subject matter in any way.

### Example 1. Patterned Growth of Conductive Metal-Organic Frameworks on Flexible Substrates Using Metallic Oxidative Restructuring

This Example describes a patterned growth of conductive metal-organic frameworks on flexible substrates using metallic oxidative restructuring.

### Example 1.1. Introduction

Two-dimensional conductive metal-organic frameworks (MOFs) are a class of emerging materials with promising applications in electronics, magnetics, energy storage, electrocatalysis, and chemical sensing. Nonetheless, the design strategies for developing customizable and stable porous electrodes are extremely limited in scope. A controlled synthesis and fabrication method is needed to streamline the device production into one step. This Example describes a novel synthetic method for the formation of MOFs by utilizing zero-oxidation state metals (M(0)) and selected organic linkers under oxidative conditions. This unprecedented synthetic method provides opportunities for the patterned growth of MOFs through self-assembly under mild synthetic conditions.

### Example 1.2. Results and Discussion

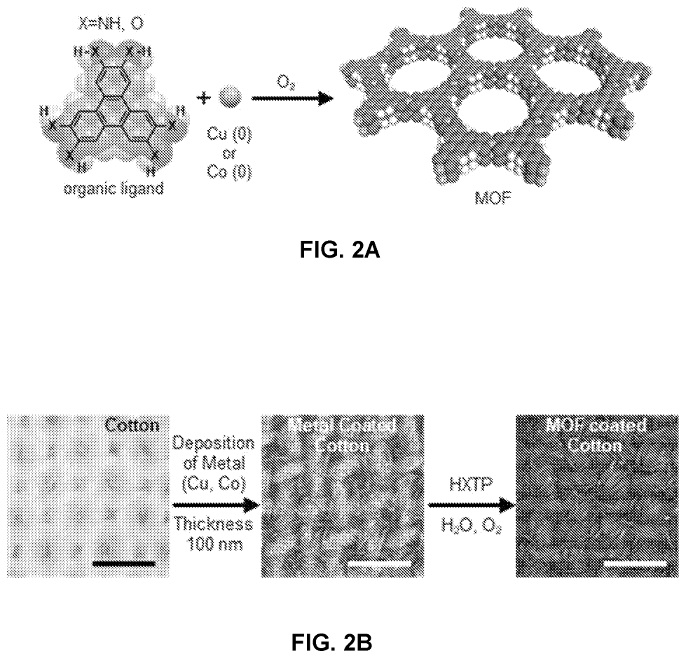

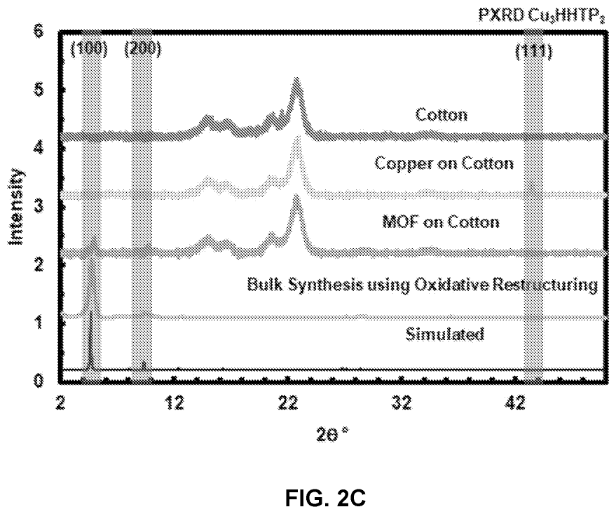

Oxidative restructuring is a new synthetic method for forming metal-organic frameworks (MOFs) as depicted in FIG. 2A. Applicants demonstrated that exposure of Cu (0) (45 μm diameter) to oxidizing agents (e.g., atmospheric O₂) facilitates the oxidation of metallic Cu (0) to Cu²⁺ ions that can subsequently interact with the organic precursor 2,3,6,7,10,11-hexahydroxytriphenylene (HHTP), 2,3,6,7,10,11-hexaaminotriphenylene (HITP), and trimesic acid (BTC), dissolved in the solution, to form two-dimensional MOFs.

Applicants investigated the formation of Cu₃HHTP₂, Co₃HHTP₂, Cu₃HITP₂, and CuBTC using X-ray powder diffraction spectroscopy (PXRD). Initial PXRD analysis of the Cu (0) powder revealed a strong peak at 43° (2θ) that has been ascribed to the [111] plane in Cu (0) particles. Shortly after placing the organic precursor in the aqueous solution containing Cu powder (approximately 5 min), Applicants visually observed the formation of black powder along with the presence of Cu powder. Subsequent PXRD pattern analysis of the collected powder confirmed the presence of key peaks corresponding to the [100] and [200] planes in Cu₃HHTP₂ MOF in slipped parallel packing mode. Nonetheless, Applicants observed that the 43° (2θ) peak was still present on the collected PXRD pattern indicating only partial formation of the Cu₃HHTP₂ MOF.

In the first situation, the incomplete formation of MOF could be due to short time of synthesis. Applicants anticipate that longer reaction time may be required to ensure full oxidation of Cu (0) powder to Cu ions. While this process is spontaneously triggered by the presence of dissolved oxygen in solution thus resulting in rapid oxidation of the outer layer of Cu powder, a much longer time would be required for the oxygen to diffuse through the MOF formed on the outer surface of the Cu particles to reach deeper layers of the Cu (0) and therefore to drive this reaction to completion. In the second situation, the unoptimized ratio of metal-ligand precursors present in the solution in which copper (0) powder is in excess leads to the incomplete reaction of Cu (0). Nonetheless, Applicants anticipate that this new synthetic method is applicable for the formation of metal-organic frameworks on a variety of metal pre-patterned substrates as well as can be expanded to other two- or three-dimensional MOFs based on other metal centers.

To further probe the generality of this novel synthetic approach, Applicants focused on the development of wearable electronics due to their potential application in environmental sensing, energy storage and point-of-care diagnostics. Applicants used Cu as a model metal due to its known ability to readily oxidize in the presence of atmospheric oxygen. Therefore, Applicants thermally evaporated a thin layer of Cu metal (100 nm) onto the cotton substrate to form a template for subsequent MOF synthesis through oxidative restructuring. Interestingly, Applicants observed that the pre-patterned cotton substrate did not conduct electricity despite the presence of metallic Cu on its surface. This observation can be explained by the intrinsic nature of acquired textiles, in which fiber separation is too large to allow bridging of evaporated Cu at lower thicknesses thus preventing charge transport.

When the thickness of the Cu layer is increased from 100 nm to 1000 nm, electrical contact between neighboring Cu particles is established giving rise to a fully conductive substrate. After placing the Cu-coated cotton into the HHTP ligand solution, Applicants immediately observed the formation of MOF. Applicants monitored the progression of this reaction using PXRD analysis, which revealed that for 100 nm thick Cu coated cotton the reaction comes to completion just under 30 min as evidenced by the disappearance of the Cu peak in PXRD (43° (2θ)—[111] plane) and subsequent formation of [100] peak at 4.7° (2θ) of the Cu₃HHTP₂ MOF (FIG. 2C). PXRD analysis also revealed the presence of cellulose diffraction peaks at 15.2° and 22.8° (2θ), representing the [101] and [002] planes, respectively. Scanning electron microscopy (SEM) of MOF-coated cotton demonstrated the presence of highly oriented MOF nano-rods, which form a continuous coating on the surface of the cotton substrate. Energy-dispersive X-ray spectroscopy (EDX) qualitatively confirmed the presence of C, O, and Cu within the bulk of material.

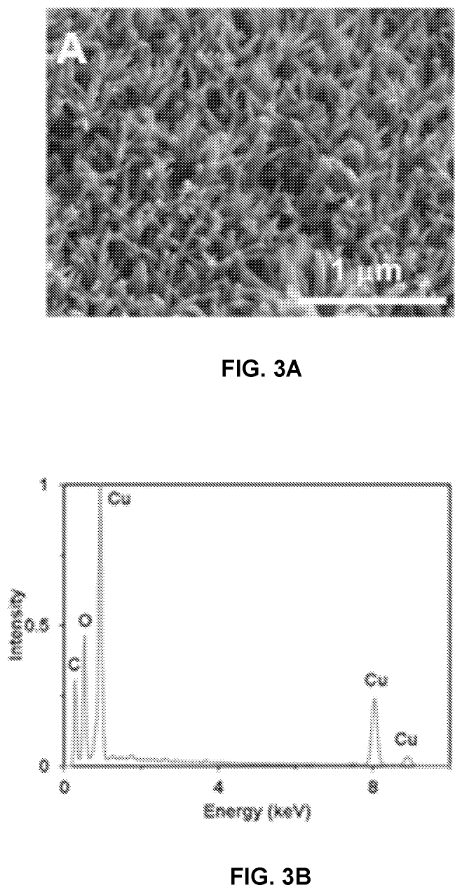

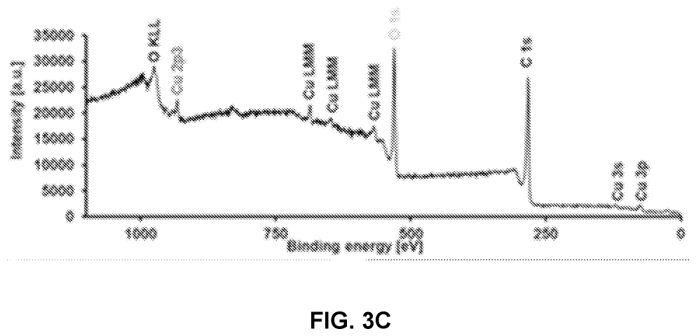

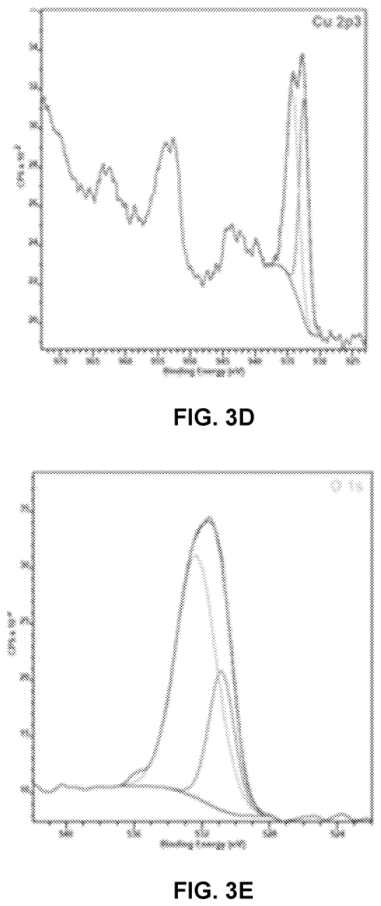

Surface analysis using X-ray photoelectron spectroscopy (XPS) also confirmed the presence of O, C, and Cu used for the preparation of Cu₃HHTP₂ MOFs (FIGS. 3A-E). High-resolution XPS analysis further demonstrated that after washing, no traces of the precursors and other extraneous species were detected in the Cu₃HHTP₂ MOF indicating the absence of potentially charge-balancing counter-ions. Further peak deconvolution of 2p region revealed the presence of two distinct chemical environments with peaks maximum at 932.5 eV and 934.3 eV indicating mixed valency (Cu⁺/Cu²) within the framework. Importantly, no elemental Cu was detected using XPS and PXRD analysis indicating large suitability of this fabrication method for the development of wearable electronics.

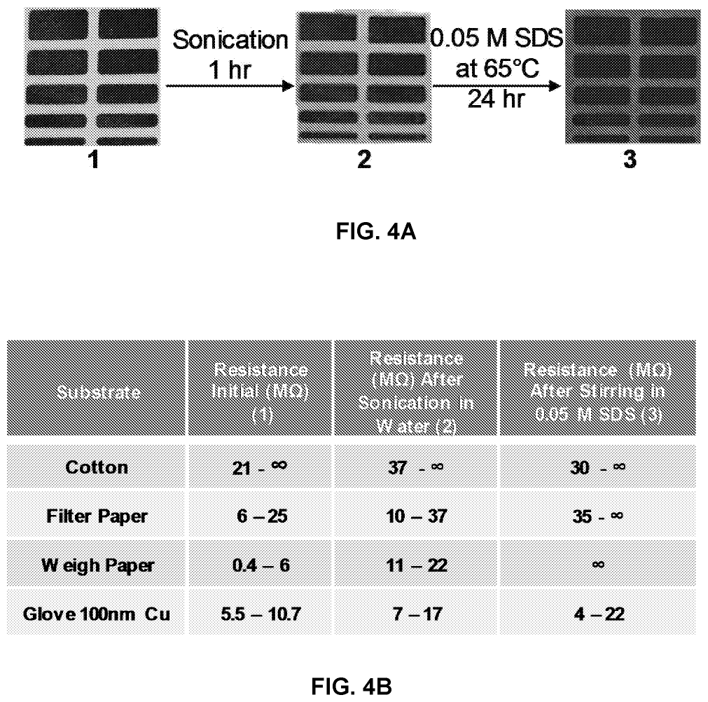

Applicants observed that pre-patterned substrates with higher surface roughness demonstrated stable adhesion of MOF onto the substrate, but nonetheless the MOFs exhibited substantial electrical conductivity with the lowest resistances of 0.4 MΩ on 1 cm×0.5 cm area, indicating successful incorporation of MOF onto the substrates. Applicants also assessed the mechanical stability of the MOF coated cotton through series of experiments in which the fabrics were exposed to physical and chemical stress through sonication for 1 hour and washing in 0.05 M solution of sodium dodecyl sulfonate (SDS) at 65° C. for 24 hours, respectively (FIGS. 4A-B). These processes mimic the extreme situations in which the electronic textiles could be exposed to in practical applications. Applicants then measured electrical conductivity to assess the degree of damage to the textiles. Interestingly, Applicants observed that Cu₃HHTP₂ MOF on substrates demonstrate optimal mechanical stability to both chemical and mechanical treatment without the significant loss of conductivity (FIG. 4B). Moreover, the conductivity of the MOF coated cotton was unaltered if further mechanical stress such as pulling or stretching was employed, indicating optimal robustness of the developed material.

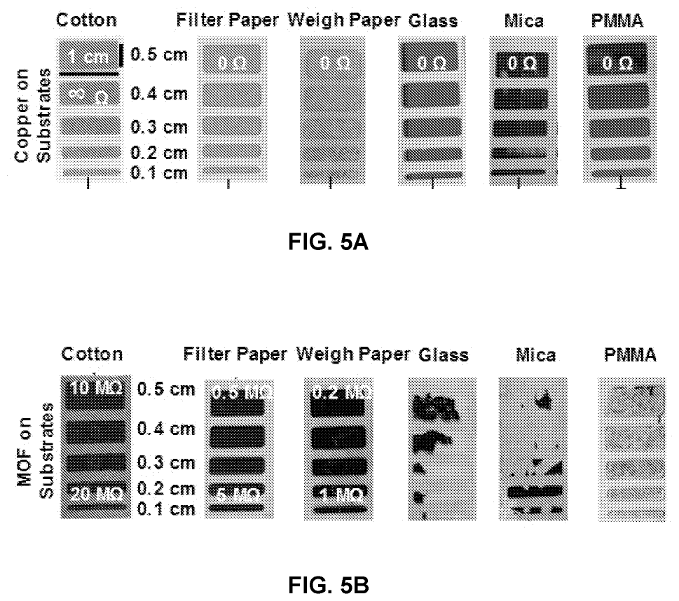

Nonetheless, the versatility of oxidative restructuring lies in the ability to deposit the choice of metal onto a variety of substrates. Therefore, Applicants deposited a 100 nm thick layer of Cu onto other substrates including filter paper, weigh paper, glass slide, and mica (FIG. 5A). The patterned Cu layer consisted of eight rectangles with dimensions of 1 cm×0.5 cm, 1 cm×0.4 cm, 1 cm×0.3 cm, 1 cm×0.2 cm, and 1 cm×0.1 cm. Oxidative restructuring successfully led to the formation of Cu₃HHTP₂ MOF onto the pre-patterned substrate. While good mechanical stability was observed for the MOF on cotton, filter, and weight paper, substantial delamination of the MOF from the surface of glass and mica was observed (FIG. 5B). Applicants hypothesize that the underlying principle that defines good adhesion and consequently mechanical stability is the inherent contact of Cu (0) with the substrate. Recent reports have demonstrated that functionalized glass with —OH groups using piranha solution can serve as an anchor for the Cu ions, and thus offers enhanced mechanical contact upon formation. Similar behavior is expected for more ‘porous’ substrates such as cotton or paper where the metal can be incorporated (e.g., in between the threads of each fiber thus providing good adhesion properties). Applicants anticipate that, in some embodiments, different methods of integrating metals onto the substrate of interest (e.g., drop-casting, painting, etc.) may dictate the extent of mechanical stability of formed MOFs.

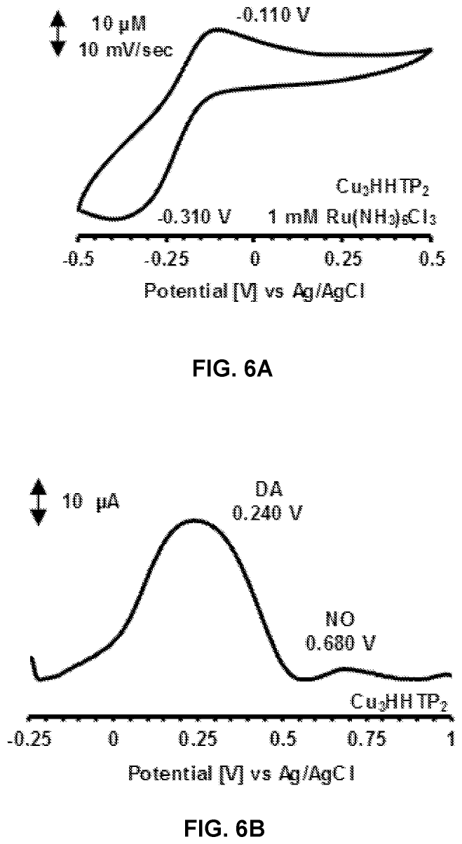

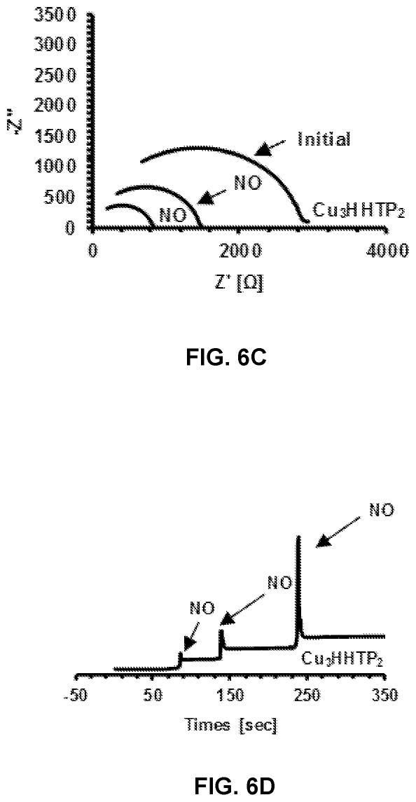

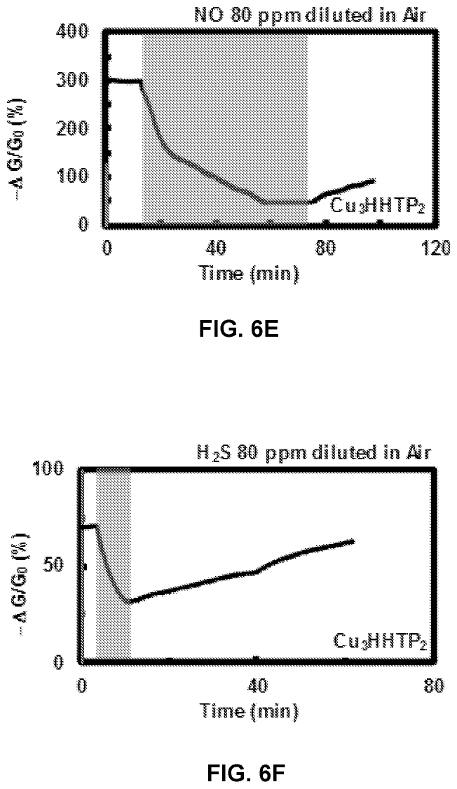

Applicants also demonstrated that the developed Cu₃HHTP₂ MOF coated cotton can be used for the detection of numerous biologically relevant analytes, including nitric oxide (NO), and dopamine (DA). Moreover, these electrochemical sensors can be used in different device architectures suitable for real-life analysis of molecules in the gas phase and solutions (FIGS. 6A-F). Applicants demonstrate that, when the Cu₃HHTP₂ is used as both an electrical conductor and sensing element/transducer in voltammetric measurements, the differentiation between dopamine and NO is possible with peak separation of 440 mV. In the same device architecture, the MOF coated cotton could successfully detect NO through electrochemical impedance spectroscopy (EIS) measurements and amperometric sensing. EIS revealed the decrease in impedance from 3.1 kΩ to 600Ω upon consecutive delivery of NO gas (introduced through 500 mL filled balloon). In addition, amperometric analysis demonstrated a strong sensing response to both NO and H₂S at 80 ppm.

### Example 1.3. Chemicals, Materials and Instruments

Chemicals and solvents were purchased from Sigma Aldrich (St. Louis, Mo.), TCI (Portland, Oreg.), Fisher (Pittsburgh, Pa.), or Alfa Aesar (Tewksbury, Mass.) and used as received. EmStat MUX16 potentiostat (Palm Instruments BV, Netherlands) and IviumStat (Ivium Technologies, Netherlands) were used for all electrochemical measurements. Scanning Electron Microscopy (SEM) and Energy Dispersive X-ray Spectroscopy (EDX) were performed using a FEI Scios (Hillsboro, Oreg.) equipped for X-ray microanalysis with a Bruker Edax light element Si(Li) detector (Billerica, Mass.). Powder X-ray diffraction (PXRD) measurements were performed with a Bruker D8 diffractometer equipped with a Ge-monochromated 2.2 kW (40 kV, 40 kA) CuKα (α=1.54 Å) radiation source and a NaI scintillation counter detector (Billerica, Mass.). X-ray photoelectron spectroscopy (XPS) experiments were conducted using an Physical Electronics Versaprobe II X-ray Photoelectron Spectrometer under ultrahigh vacuum (base pressure 10⁻¹⁰ mbar). The measurement chamber was equipped with a monochromatic Al (Kα) X-ray source. Both survey and high-resolution spectra were obtained using a beam diameter of 200 μm. The spectra were processed with CasaXPS software. Thermal Evaporator (Angstrom Engineering, Ontario, Canada). Weigh paper (Cat. No. 12578-121) was purchased from VWR International (Randor, Pa.). Cotton fabric (White Solid FQ 5960141) was purchased from Fabric Quarter. Filter paper (Cat. No. 1450-125) was purchased from VWR International (Randor, Pa.).

### Example 1.4. Synthesis: Synthesis of M₃HXTP₂

Oxidative Restructuring Synthesis of MOFs using Metal Powder: To a 20 mL scintillation vial, organic linker (2 equivalence) and metal powder (3 equivalence) was added. Deionized water (0.0144 M respect to the organic linker) was added to the vial. The reaction mixture was placed under an air stream in room temperature for 1 hour.

Cu₃HHTP₂: To a 20 mL scintillation vial HHTP (50 mg, 0.154 mmol) and Cu (0) metal powder (45 μm diameter, 18.24 mg, 0.285 mmol) was added. 10 ml of deionized water (0.0144 M respect to the organic linker) was added to the vial. The reaction mixture was placed under an air stream at room temperature for 1 hour. The product was then filtered with a ceramic funnel and filter paper and washed with deionized water (3×50 mL) and with acetone (3×50 mL). The solid product on the filter paper was then transferred to a vial and dried overnight under vacuum (20 mTorr) at 85° C.

Oxidative Restructuring Synthesis of MOFs using Patterned Metal: To a 20 mL scintillation vial organic linker (100 equivalence) and patterned metal substrate was added. Deionized water (0.0072 M respect to the organic linker) was added to the vial. The reaction mixture was placed under an air stream in room temperature for 1 hour.

Cu₃HHTP₂ grown on substrate: To a 200 mL glass dish HHTP (50 mg, 0.154 mmol) and copper coated substrate was added. 50 ml of deionized water (0.003 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

Co₃HHTP₂ grown on substrate: To a 200 mL glass dish HHTP (50 mg, 0.154 mmol) and cobalt coated substrate was added. 50 ml of deionized water (0.003 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

Cu₃HITP₂ grown on substrate: To a 200 mL glass dish HITP (50 mg, 0.093 mmol) and copper coated substrate was added. 50 ml of deionized water (0.002 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

CuBTC grown on substrate: To a 200 mL glass dish trimesic acid (50 mg, 0.237 mmol) and copper coated substrate was added. 50 ml of deionized water (0.005 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

### Example 1.5. Metal Pattern Substrates: Deposition of Metal

Copper (99.99% purity) was deposited onto substrates of interest—cotton, filter paper, weighing paper, mica (100 nm thickness)—through a metal stencil mask with a patterns of rectangular boxes that range from 1 cm×0.5, 1 cm×0.4, 1 cm×0.3, 1 cm×0.2, 1 cm×0.1 (Angstrom Engineering, Ontario, Canada) using a Thermal Evaporator (Angstrom Engineering, Ontario, Canada) under a pressure of 0.5×10⁻⁵ Torr and a rate of evaporation of 1 Å/s.

### Example 1.6. Electrochemical Characterization of M₃HXTP₂ Modified Electrodes: Cyclic Voltammetry for the Elucidation of Redox Properties of Cu₃HHTP₂ Using Ru(NH₃)₆Cl₃ Redox Probe

The cyclic voltammetry experiments were performed using a three-electrode system including a 1.5 cm×1.5 cm piece of Cu₃HHTP₂ MOF coated fabric working electrode, a reference electrode: Ag/AgCl electrode, and a platinum wire counter electrode. The background electrolyte was 10 mL of 0.1 M potassium chloride (KCl) containing 1 mM of hexaammineruthenium(II) chloride (Ru(NH₃)₆Cl₃). Before all experiments, the solutions were degassed by bubbling nitrogen gas for 30 min.

### Example 1.7. Differential Pulse Voltammetry

Differential pulse voltammetry was performed using a three-electrode system including a 1.5 cm×1.5 cm piece of Cu₃HHTP₂ MOF coated fabrics, a reference electrode: Ag/AgCl electrode, and a platinum wire counter electrode. The supporting electrolyte was 0.1 M PBS (pH=7.4). DPV experimental parameters: scan rate: 50 mV/sec; pulse width: 50 msec; and amplitude: 50 mV. Before all experiments, the solutions were degassed by bubbling nitrogen gas for 30 min. The individual and simultaneous determination of DA and NO were achieved by measuring the oxidation peak currents with respect to the concentrations of the respective analytes.

### Example 1.8. Amperometric Measurements in Solution

A constant potential of +0.5 V was applied to the working electrode (1.5 cm×1.5 cm piece of Cu₃HHTP₂ MOF coated fabric) for 360 s. The resulting current was recorded in a solution of 0.1 M PBS (pH=7.4) at room temperature. All measurements were carried out in a three-electrode configuration. The reference electrode was an Ag/AgCl and the auxiliary electrode was a platinum wire. Before all experiments, the solutions were degassed by bubbling nitrogen gas for 30 min. The NO was delivered to the solution through a balloon filled with approximately 500 mL of the gas.

### Example 1.9. Electrochemical Impedance Spectroscopy

All impedance measurements were performed by using an Ivium Technologies CompactStat Impedance Analyser (Ivium Technologies). The EIS measurements of the MOF coated fabrics were conducted using established techniques. Briefly, impedance spectra were collected using excitation amplitude of 0.01 V within the frequency range spanning from 100 kHz to 0.1 Hz. A conventional three electrodes set-up was used for all impedance measurements using a 1.5 cm×1.5 cm piece of Cu₃HHTP₂ MOF coated fabric, platinum auxiliary electrode and a silver-silver chloride electrode as the reference. Each measurement was performed at open-circuit potential in 0.1 M PBS (pH=7.4) at room temperature. All impedance spectra were fitted to equivalent circuits using the IviumStat software version 2.0.

### Example 1.10. Chemiresistive Sensing: General Methods

For chemiresistive sensing measurements, a custom Teflon enclosure equipped with inlet and outlet ports was fabricated, and equipped with 10 spring-loaded gold pins, which served to immobilize the MOF coated fabric and make electrical contacts with external wires (5 swatches per enclosure). A PalmSense EmStatMUX potentiostat with a 16-channel multiplexer was connected to the enclosure wires through a breadboard, and the data collected using PSTrace 5 software. Unless otherwise specified, sensing experiments were performed under a constant applied voltage of 1.0 V. Data was normalized and processed. The chamber inlet was connected to a gas or vapor delivery system for controlled concentration gas sensing measurements.

### Example 2. Growth of Conductive Metal-Organic Frameworks Using Metallic Oxidative Restructuring

This Example also describes the growth of conductive metal-organic frameworks using metallic oxidative restructuring. In this Example, zero-oxidation state metals are also referred to as zero-valent metals.

### Example 2.1 Oxidative Restructuring Synthesis

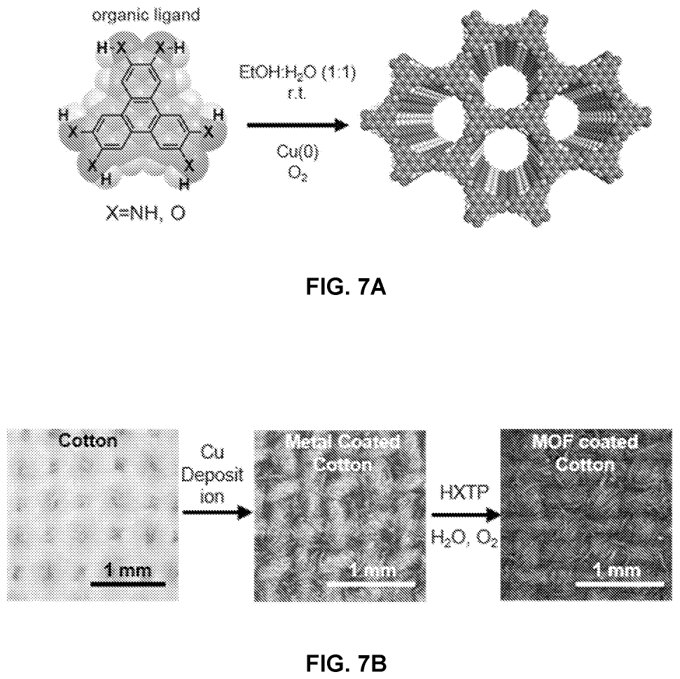

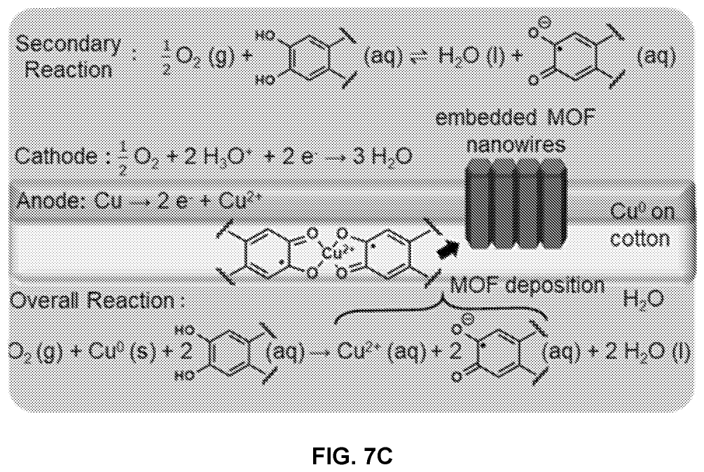

In solvothermal metal-organic framework (MOF) synthesis, the desired metal salt, organic ligand, solvent, high temperature and oxidant and/or base are all important factors in forming the extended framework. Oxidative restructuring in this Example has two key differences: i) the metal source is from a zero-valent source; and ii) the synthesis is conducted at room temperature (FIG. 7A).

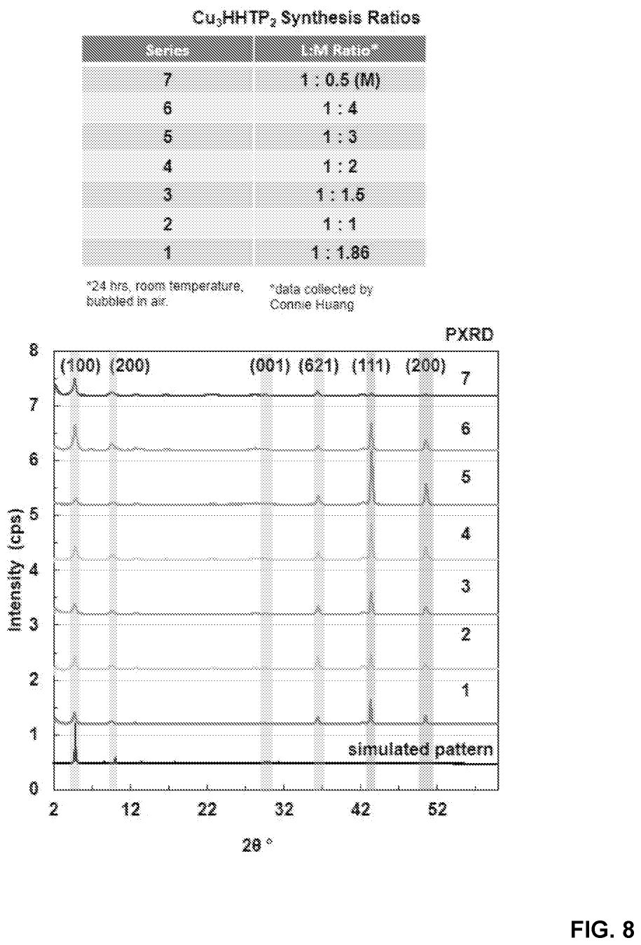

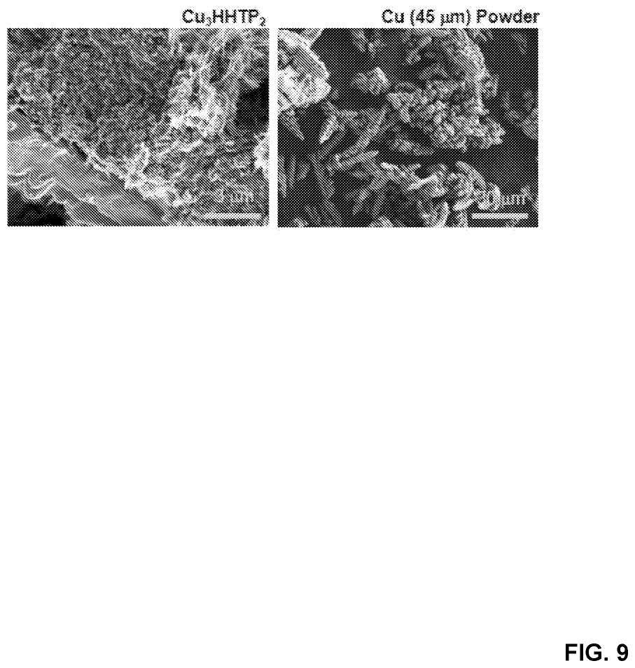

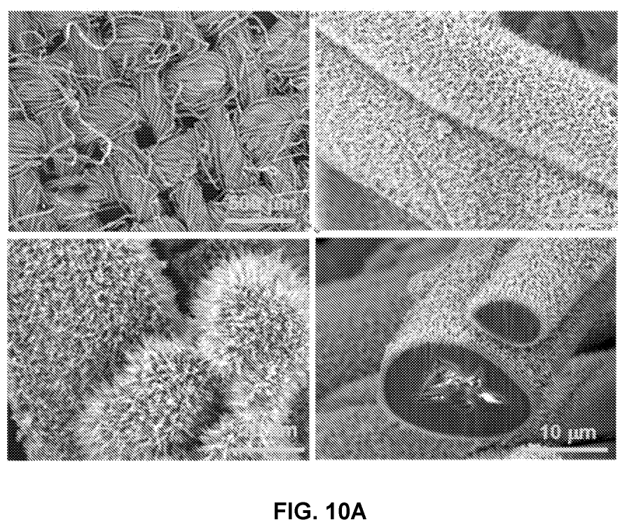

In this method, 2,3,6,7,10,11-hexahydroxytriphenylene (HHTP) is dissolved in 1:1 mixture of EtOH and H₂O followed by the addition of the zero-valent Cu metal particles. The reaction proceeds under ambient air forming Cu₃HHTP₂ MOFs in solution. The transformation of the metallic Cu particles to MOFs can be observed in powder X-ray diffraction (PXRD), but not without the remaining unwanted Cu particles present (FIG. 8). PXRD pattern analysis of the collected powder confirmed the presence of key peaks corresponding to the [100] and [200] planes in Cu₃HHTP₂ MOF in slipped parallel packing mode. Applicants observed that the 43° (2θ) peak was still present that corresponds to the remaining Cu metal particle. Using metal-to-ligand ratios for traditional synthesis is not viable in oxidative restructuring because the remaining unreacted zero-oxidation state metal is undesired. Therefore, a study on the role of the metal-to-ligand ratio and how that affects the overall reaction completion was investigated on the Cu₃HHTP₂ based MOFs (FIG. 8).

Lowering the metal molar ratio in the synthesis of the MOFs helped reduce the remaining Cu particles, but the overall yield of the MOF was also reduced. The morphology of the MOFs and Cu metal particle was analyzed using scanning electron microscopy (SEM) (FIG. 9). Cu₂HHTP₂ formed using solvothermal synthesis produced nanorod morphology whereas in oxidative restructuring the MOFs featured a mixture between small nanorods and amorphous morphology (FIG. 9). To explore the versatility of this method, Applicants expanded this method by depositing the zero-valent Cu to substrates (FIG. 7B).

### Example 2.2. Fabrication of MOFs on Substrates Using Oxidative Restructuring

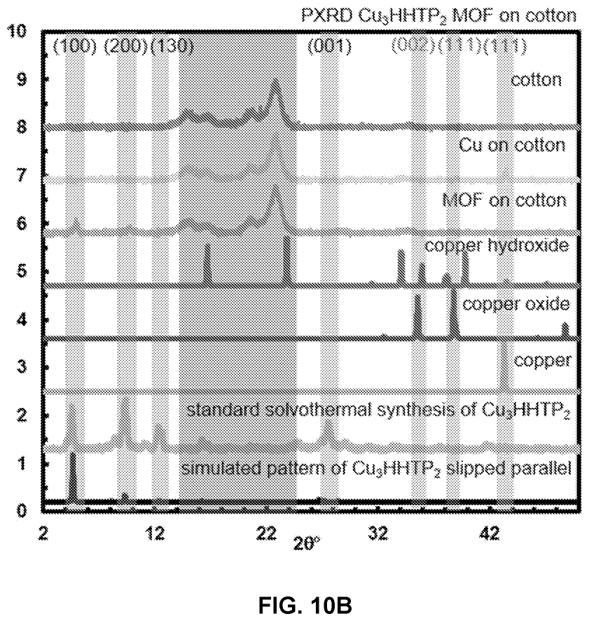

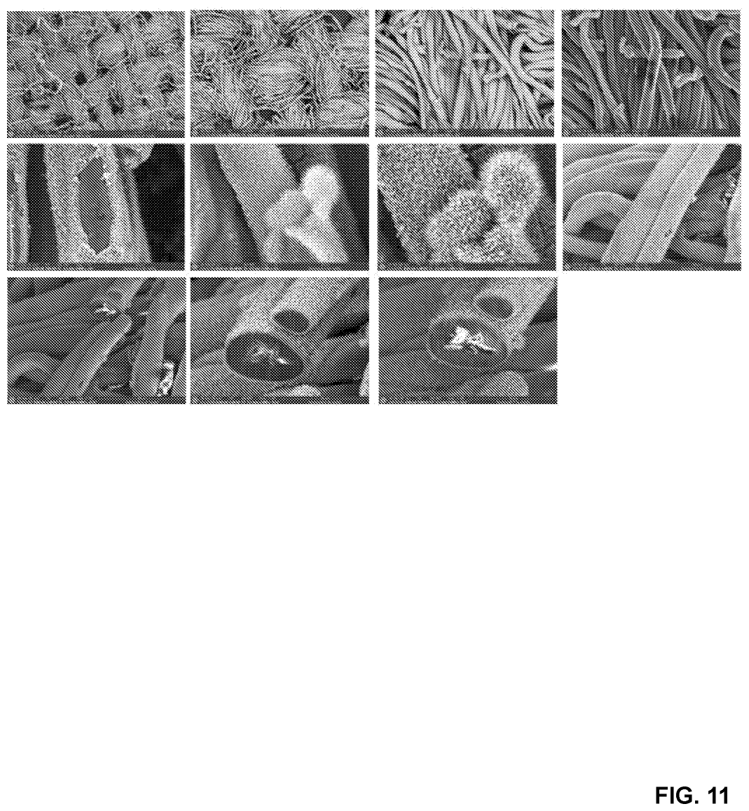

Applicants chose to investigate a wide variety of substrates that span from natural and synthetic polymers, but the focus has been on the use of textiles. To achieve the formation of MOFs on textiles first, Applicants thermally evaporated a thin layer of Cu metal (100 nm) onto the cotton substrate to form a template for subsequent MOF synthesis through oxidative restructuring (FIG. 7B). Applicants observed that the pre-patterned cotton substrate did not conduct electricity despite the presence of metallic Cu on its surface. This observation can be explained by the intrinsic nature of purchased textiles, in which fiber separation is too large to allow bridging of evaporated Cu at lower thicknesses thus preventing charge transport. When the thickness of the Cu layer is increased from 100 nm to 1000 nm, electrical contact between neighboring Cu particles is established giving rise to a fully conductive substrate. Interestingly, after placing the Cu-coated cotton into the HHTP ligand solution, Applicants observed the formation of MOF directly on the cotton (FIG. 7B). Scanning electron microscopy (SEM) of Cu₃HHTP₂ MOF-coated cotton demonstrated the presence of highly oriented MOF nanorods, which form a continuous coating on the surface of the cotton substrate (FIGS. 10A and 11). Cross-sectional SEM reveals the coating of the MOF occurs entirely around the circumference of individual cotton fibers (FIGS. 10A and 11).

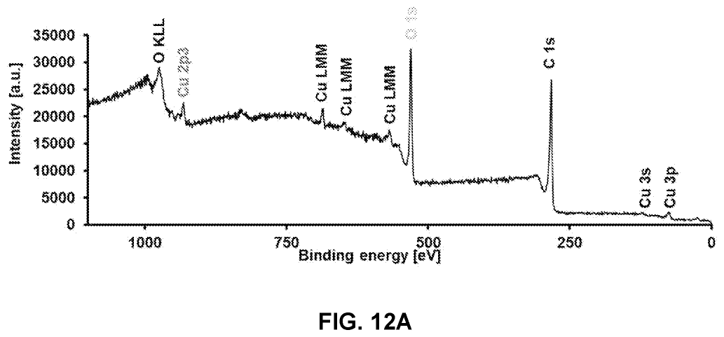

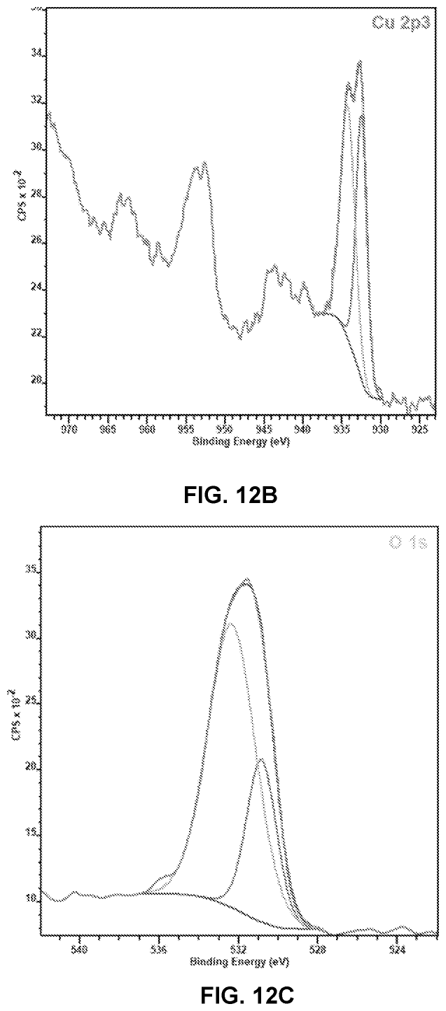

PXRD analysis for MOF Cu₃HHTP₂ revealed that for 100 nm thick Cu coated cotton, the reaction comes to completion just under 30 min as evidenced by the disappearance of the Cu peak in PXRD (43° (2θ)—[111] plane) and subsequent formation of [100] peak at 4.7° (2θ) of the Cu₃HHTP₂ MOF (FIG. 10B). PXRD analysis also revealed the presence of cellulose diffraction peaks at 15.2° and 22.8° (2θ), representing the [101] and [002] planes, respectively. Surface analysis on Cu₃HHTP₂ on cotton using X-ray photoelectron spectroscopy (XPS) also confirmed the presence of O, C, and Cu used for the preparation of Cu₃HHTP₂ MOFs (FIGS. 12A-C). High-resolution XPS analysis further demonstrated that after washing, no traces of the precursors and other extraneous species were detected in the Cu₃HHTP₂ MOF, indicating the absence of potentially charge-balancing counter-ions. Further peak deconvolution of 2p region revealed the presence of two distinct chemical environments with peaks maximum at 932.5 eV and 934.3 eV, indicating mixed valency (Cu⁺/Cu²) within the framework.

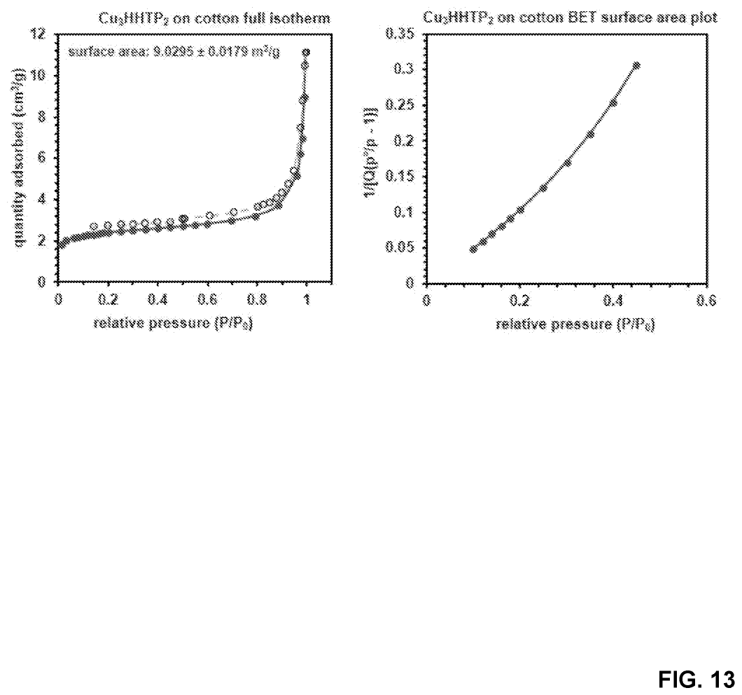

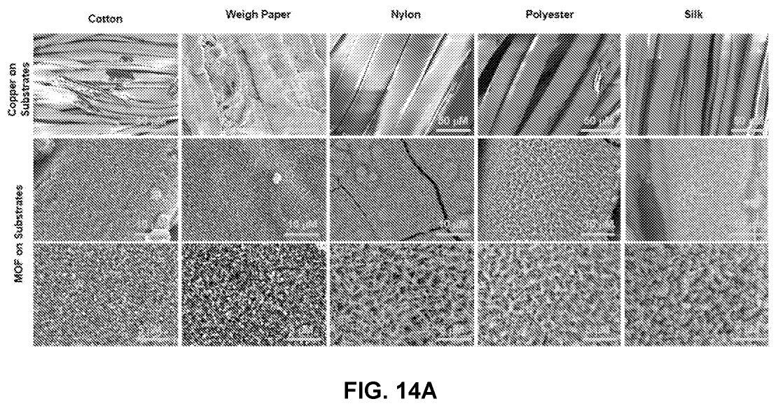

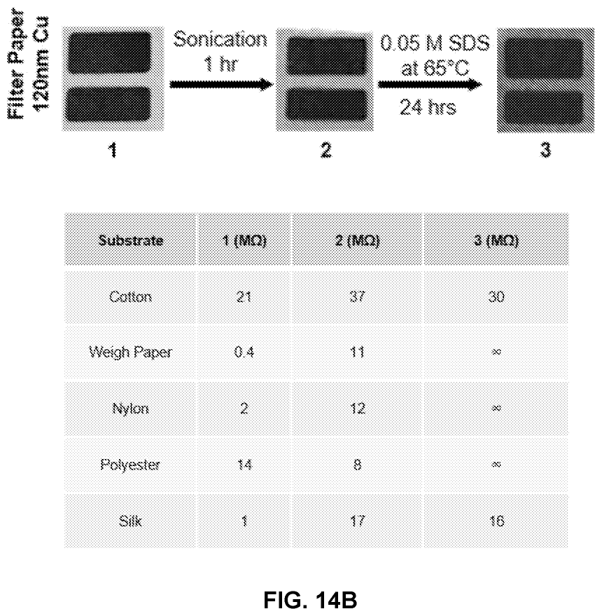

The surface area of Cu₃HHTP₂ coated on cotton was measured using Brunauer-Emmett-Teller (BET). The analysis displayed type IV isotherms with the hysteresis cycles, indicating the presence of nanopores. The specific surface area calculated using BET analysis for Cu₃HHTP₂ on cotton was 9.02 m²/g which is much greater compared to the surface area of unmodified cotton (0.3 m²/g) (FIG. 13). The versatility of oxidative restructuring lies in the ability to deposit the metal precursor onto a variety of substrates. Therefore, Applicants deposited a 100 nm thick layer of Cu onto other substrates including filter paper, weigh paper, silk, and nylon (FIG. 14A).

The patterned Cu layer consisted of eight rectangles with dimensions of 1 cm×0.5 cm, and 1 cm×0.4 cm. Oxidative restructuring successfully led to the formation of Cu₃HHTP₂ MOF onto the pre-patterned substrate. The MOFs grown on substrates using oxidative restructuring demonstrated variable stability to physical and chemical stresses. MOFs grown on textiles such as cotton that possess higher surface roughness demonstrated stable adhesion of MOF onto the substrate. The mechanical stability of the Cu₃HHTP₂ MOF coated cotton was investigated through series of experiments in which the fabrics were exposed to physical and chemical stress through sonication for 1 hour and washing in 0.05 M solution of SDS at 65° C. for 24 hours, respectively (FIG. 14B). These processes mimic the extreme situations in which the electronic textiles could be exposed to in practical applications. Applicants then measured electrical conductivity to assess the degree of damage to the textiles. Applicants observed that Cu₃HHTP₂ MOF on substrates demonstrates optimal mechanical stability to both chemical and mechanical treatment without the significant loss of conductivity (FIG. 14B). The conductivity of the MOF coated cotton was unaltered if further mechanical stress such as pulling or stretching was employed, indicating optimal robustness of the developed material.

### Example 2.3. Chemical Detection in Gas Phase

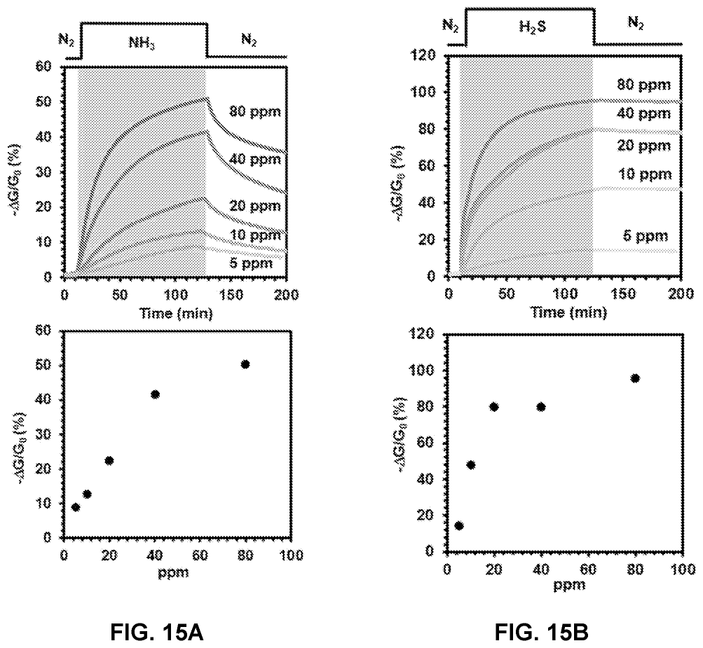

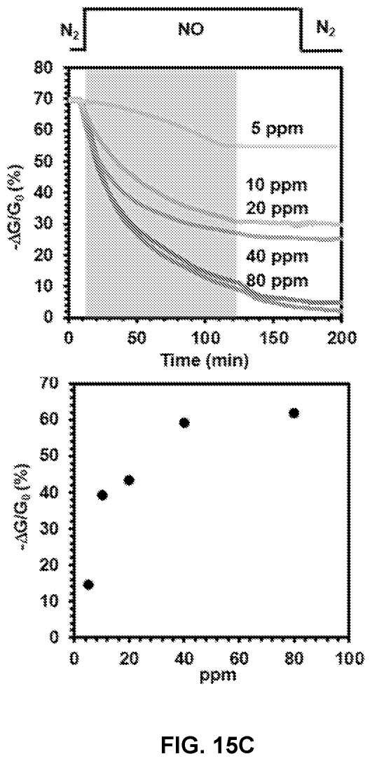

The demonstration of flexible devices for the detection of biologically relevant and toxic gases (e.g., NH₃, H₂S, and NO) has been demonstrated. The multifunctional devices were fabricated using oxidative restructuring to form Cu₃HHTP₂ MOFs with strong interfacial contact on the various substrates. The flexible devices (1.5 cm×0.5 cm) were placed into an airtight custom Teflon enclosure with gold pins to contact the flexible devices. A potential of one volt was applied through the devices and the current was read out through a potentiostat. Controlled doses of desired analytes were delivered to the enclosure using a mass flow controller and the gaseous analytes (NH₃, H₂S, and NO) were further diluted using N₂. Each gas at a specific concentration (80, 40, 20, 10, or 5 ppm) was delivered for two hours followed by a recovery period of two hours with only the N₂ stream. The devices with Cu₃HHTP₂ MOF exhibited a response to NH₃, H₂S, and NO illustrated in FIGS. 15A-C with the normalized response (−ΔG/G₀).

The response towards 80 ppm of NH₃ reached 50% with partial recovery. H₂S and NO delivered at 80 ppm concentration exhibited dosimetric response at 60%, and 95% respectively (FIG. 15A). The saturation event of the devices was clearly observed in the case of H₂S, which occurred before the two-hour exposure period, but in the case of NH₃ and NO, the devices did not have a saturated response. Each analyte was studied further with exposures to the MOF coated cotton at concentrations of 5, 10, 20, 40, and 80 ppm (FIG. 15B). The devices had a linear response to NH₃ (R²=0.90), but for H₂S, and NO there were two linear ranges observed at 5-20 ppm and 20-80 ppm.

Applicants demonstrate that when the Cu₃HHTP₂ is used as both an electrical conductor and sensing element/transducer in voltammetric measurements, the differentiation between dopamine and NO is possible with peak separation of 440 mV. In the same device architecture, the MOF coated cotton could successfully detect NO through electrochemical impedance spectroscopy (EIS) measurements and amperometric sensing. EIS revealed the decrease in impedance from 3.1 kΩ to 600Ω upon consecutive delivery of NO gas (introduced through 500 mL filled balloon).

### Example 2.4. Chemicals, Materials and Instruments

Chemicals and solvents were purchased from Sigma Aldrich (St. Louis, Mo.), TCI (Portland, Oreg.), Fisher (Pittsburgh, Pa.), or Alfa Aesar (Tewksbury, Mass.) and used as received. EmStat MUX16 potentiostat (Palm Instruments BV, Netherlands) and IviumStat (Ivium Technologies, Netherlands) were used for all electrochemical measurements. Scanning Electron Microscopy (SEM) and Energy Dispersive X-ray Spectroscopy (EDX) were performed using a FEI Scios (Hillsboro, Oreg.) equipped for X-ray microanalysis with a Bruker Edax light element Si(Li) detector (Billerica, Mass.). Powder X-ray diffraction (PXRD) measurements were performed with a Bruker D8 diffractometer equipped with a Ge-monochromated 2.2 kW (40 kV, 40 kA) CuKα (α=1.54 Å) radiation source and a NaI scintillation counter detector (Billerica, Mass.). X-ray photoelectron spectroscopy (XPS) experiments were conducted using a Physical Electronics Versaprobe II X-ray Photoelectron Spectrometer under ultrahigh vacuum (base pressure 10⁻¹⁰ mbar). The measurement chamber was equipped with a monochromatic Al (Kα) X-ray source. Both survey and high-resolution spectra were obtained using a beam diameter of 200 μm. The spectra were processed with CasaXPS software. Thermal Evaporator (Angstrom Engineering, Ontario, Canada). Weigh paper (Cat. No. 12578-121) was purchased from VWR International (Randor, Pa.). Cotton fabric (White Solid FQ 5960141) was purchased from Fabric Quarter. Filter paper (Cat. No. 1450-125) was purchased from VWR International (Randor, Pa.).

### Example 2.5. Synthesis: Synthesis of M₃HXTP₂

Oxidative Restructuring Synthesis of MOFs using Metal Powder: To a 20 mL scintillation vial organic linker (2 equivalence) and metal powder (3 equivalence) was added. Deionized water (0.0144 M respect to the organic linker) was added to the vial. The reaction mixture was placed under an air stream in room temperature for 1 hour.

Cu₃HHTP₂: To a 20 mL scintillation vial HHTP (50 mg, 0.154 mmol) and Cu (0) metal powder (45 μm diameter, 18.24 mg, 0.285 mmol) was added. 10 ml of deionized water (0.0144 M respect to the organic linker) was added to the vial. The reaction mixture was placed under an air stream at room temperature for 1 hour. The product was then filtered with a ceramic funnel and filter paper and washed with deionized water (3×50 mL) and with acetone (3×50 mL). The solid product on the filter paper was then transferred to a vial and dried overnight under vacuum (20 mTorr) at 85° C.

Oxidative Restructuring Synthesis of MOFs using Patterned Metal: To a 20 mL scintillation vial organic linker (100 equivalence) and patterned metal substrate was added. Deionized water (0.0072 M respect to the organic linker) was added to the vial. The reaction mixture was placed under an air stream in room temperature for 1 hour.

Cu₃HHTP₂ Grown on Substrate: To a 200 mL glass dish HHTP (50 mg, 0.154 mmol) and copper coated substrate was added. 50 ml of deionized water (0.003 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

Co₃HHTP₂ Grown on Substrate: To a 200 mL glass dish HHTP (50 mg, 0.154 mmol) and cobalt coated substrate was added. 50 ml of deionized water (0.003 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

Cu₃HITP₂ Grown on Substrate: To a 200 mL glass dish HITP (50 mg, 0.093 mmol) and copper coated substrate was added. 50 ml of deionized water (0.002 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

CuBTC Grown on Substrate: To a 200 mL glass dish trimesic acid (50 mg, 0.237 mmol) and copper coated substrate was added. 50 ml of deionized water (0.005 M respect to the organic linker) was added to the glass dish. The reaction mixture was placed under an air stream at room temperature for 1 hour. The substrate was collected from the reaction solution and washed with deionized water (3×50 mL) and with acetone (3×50 mL). The solid product on the filter paper was then transferred to a vial and dried overnight under vacuum (20 mTorr) at 85° C.

### Example 2.6. Metal Pattern Substrates: Deposition of Metal

Copper (99.99% purity) was deposited onto substrates of interest (cotton, filter paper, weighing paper, mica (100 nm thickness) through a metal stencil mask with a patterns of rectangular boxes that range from 1 cm×0.5, 1 cm×0.4, 1 cm×0.3, 1 cm×0.2, 1 cm×0.1 (Angstrom Engineering, Ontario, Canada) using a Thermal Evaporator (Angstrom Engineering, Ontario, Canada) under a pressure of 0.5×10⁻⁵ Torr and a rate of evaporation of 1 Å/s.

### Example 2.7. Electrochemical Characterization of M₃HXTP₂ Modified Electrodes, Deposition of Metal Organic Frameworks (MOFs) onto Electrodes, and Cyclic Voltammetry for the Elucidation of Redox Properties of Cu₃HHTP₂ Using Ru(NH₃)₆Cl₃ Redox Probe

The cyclic voltammetry experiments were performed using a three-electrode system including a 1.5 cm×1.5 cm piece of Cu₃HHTP₂ MOF coated fabric working electrode, a reference electrode: Ag/AgCl electrode, and a platinum wire counter electrode. The background electrolyte was 10 mL of 0.1 M potassium chloride (KCl) containing 1 mM of hexaammineruthenium(II) chloride (Ru(NH₃)₆Cl₃). Before all experiments, the solutions were degassed by bubbling nitrogen gas for 30 min.

### Example 2.8. Differential Pulse Voltammetry

Differential pulse voltammetry was performed using a three-electrode system including a 1.5 cm×1.5 cm piece of Cu₃HHTP₂ MOF coated fabrics, a reference electrode: Ag/AgCl electrode, and a platinum wire counter electrode. The supporting electrolyte was 0.1 M PBS (pH=7.4). DPV experimental parameters: scan rate: 50 mV/sec; pulse width: 50 msec; and amplitude: 50 mV. Before all experiments, the solutions were degassed by bubbling nitrogen gas for 30 min. The individual and simultaneous determination of DA and NO were achieved by measuring the oxidation peak currents with respect to the concentrations of the respective analytes.

### Example 2.9. Amperometric Measurements in Solution

A constant potential of +0.5 V was applied to the working electrode (1.5 cm×1.5 cm piece of Cu₃HHTP₂ MOF coated fabric) for 360 s. The resulting current was recorded in a solution of 0.1 M PBS (pH=7.4) at room temperature. All measurements were carried out in a three-electrode configuration. The reference electrode was an Ag/AgCl and the auxiliary electrode was a platinum wire. Before all experiments, the solutions were degassed by bubbling nitrogen gas for 30 min. The NO was delivered to the solution through a balloon filled with approximately 500 mL of the gas.

### Example 2.10. Electrochemical Impedance Spectroscopy

All impedance measurements were performed by using an Ivium Technologies CompactStat Impedance Analyser (Ivium Technologies). The EIS measurements of the MOF coated fabrics were conducted using established techniques. Briefly, impedance spectra were collected using excitation amplitude of 0.01 V within the frequency range spanning from 100 kHz to 0.1 Hz. A conventional three electrodes set-up was used for all impedance measurements using a 1.5 cm×1.5 cm piece of Cu₃HHTP₂ MOF coated fabric, platinum auxiliary electrode and a silver-silver chloride electrode as the reference. Each measurement was performed at open-circuit potential in 0.1 M PBS (pH=7.4) at room temperature. All impedance spectra were fitted to equivalent circuits using the IviumStat software version 2.0.

### Example 2.11. Chemiresistive Sensing: General Methods

For chemiresistive sensing measurements, a custom Teflon enclosure equipped with inlet and outlet ports was fabricated, and equipped with 10 spring-loaded gold pins, which served to immobilize the MOF coated fabric and make electrical contacts with external wires (5 swatches per enclosure). A PalmSense EmStatMUX potentiostat with a 16-channel multiplexer was connected to the enclosure wires through a breadboard, and the data collected using PSTrace 5 software. Unless otherwise specified, sensing experiments were performed under a constant applied voltage of 1.0 V. Data was normalized and processed. The chamber inlet was connected to a gas or vapor delivery system for controlled concentration gas sensing measurements.

### Example 2.12. Cyclic Voltammetry of Cu₃HHTP₂ with a Ru(NH₃)₆Cl₃ Redox Probe, Differential Pulse Voltammetry of Cu₃HHTP₂ with Dopamine and Nitric Oxide, and Electrochemical Impedance of Cu₃HHTP₂ with NO

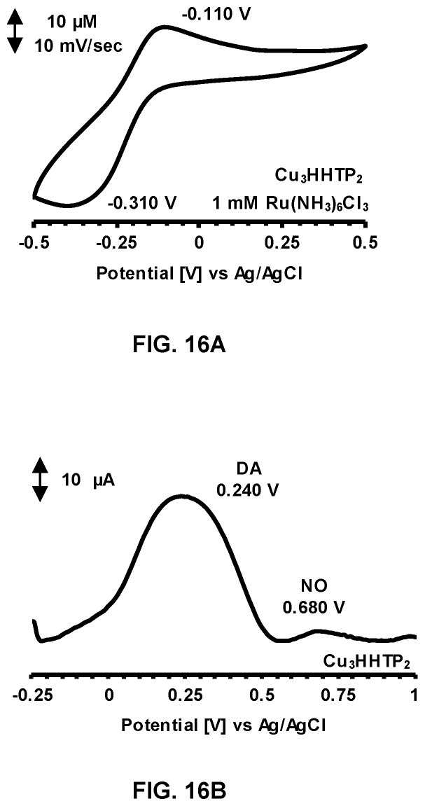

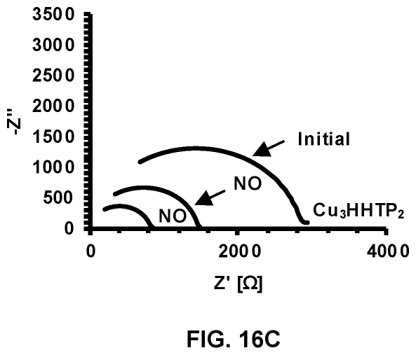

FIG. 16A illustrates cyclic voltammetry of Cu₃HHTP₂ with a Ru(NH₃)₆Cl₃ redox probe. Experimental conditions: 0.1 M KCl containing 1 mM of Ru(NH₃)₆Cl₃ under nitrogen atmosphere. Scan rate: 10 mV/sec. FIG. 16B illustrates differential pulse voltammetry of Cu₃HHTP₂ with dopamine and nitric oxide. Experimental conditions: 0.1 M PBS buffer (pH=7.4) under nitrogen, 50 mV/sec; DA 10⁻⁵; NO delivered through a balloon approximately 500 mL total. Ag/AgCl and platinum wire were used as reference and counter electrodes, respectively. FIG. 16C illustrates electrochemical impedance of Cu₃HHTP₂ with NO. Experimental conditions: 0.1 M PBS buffer (pH=7.4) under nitrogen. 10 mV amplitude, 100 kHz-0.1 Hz; NO delivered through a balloon filled with approximately 500 mL total.

### Example 2.13. Sensing Performance of Cu₃HHTP₂ on Cotton as Chemiresistors when Exposed to Gaseous Analyte

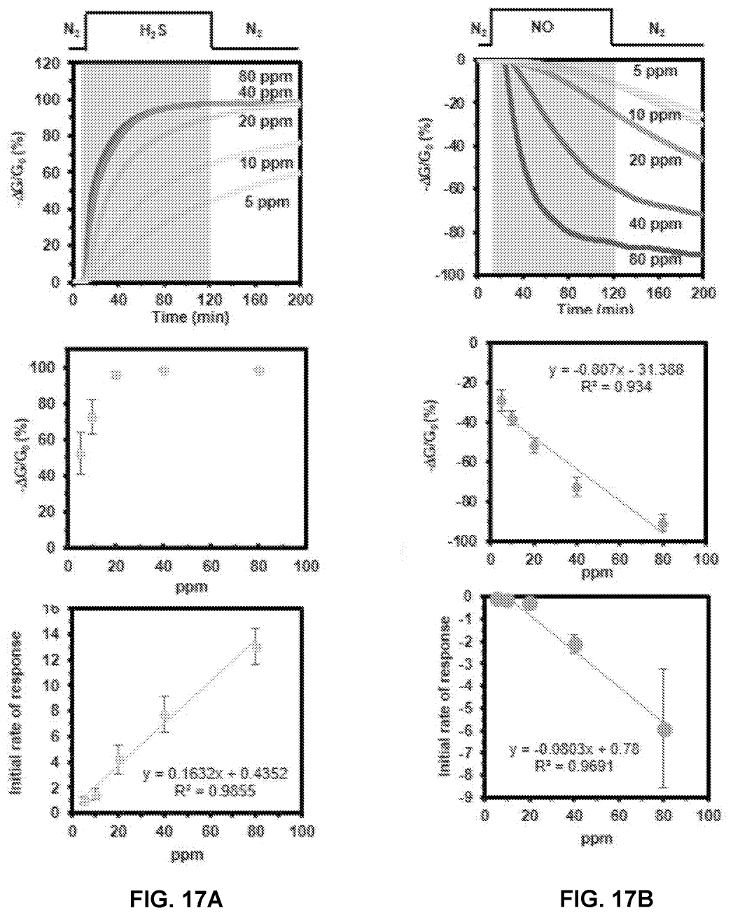

FIGS. 17A and 17B illustrate representative sensing traces show in the change in conductance −ΔG/G₀ (%) over time (min) exposed to two different gasses: H₂S (FIG. 17A) and NO (FIG. 17B) ranging from 5-80 ppm diluted with N₂ at room temperature. The grey region represents the duration of exposure to the analyte and the white region represents baseline and recovery in N₂. Concentration dependence plots of sensing response of the Cu₃HHTP₂ MOF on cotton to H₂S and No (5-80 ppm) reveal a linear response from 5-20 ppm for H₂S with saturation occurring after 20 ppm whereas NO has a linear response from 5-40 ppm and a saturation event after 40 ppm. The initial rates of response at each specific concentration show a stronger linear response compared to the overall change in response.

### Example 2.14. CoHHTP PXRD

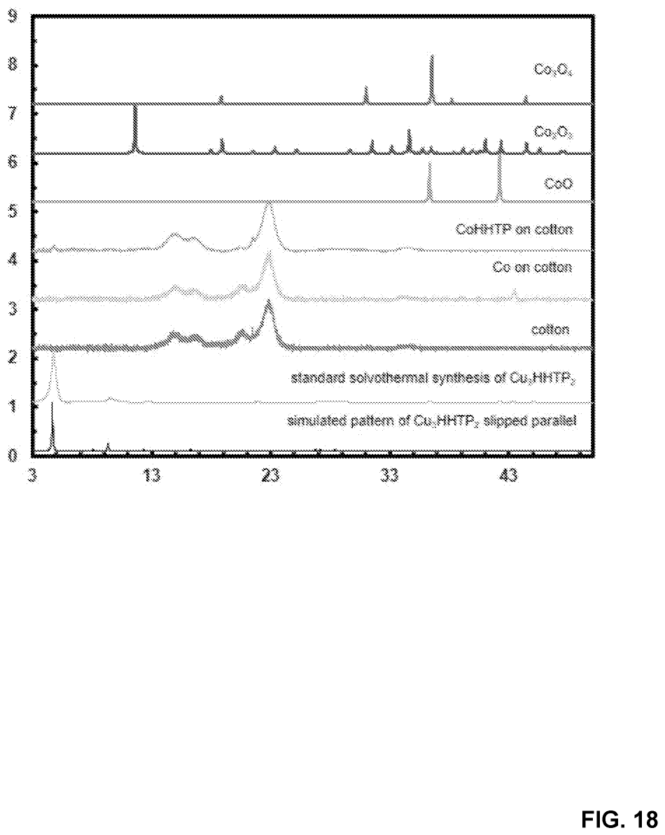

FIG. 18 illustrates CoHHTP PXRD.

### Example 2.15. Substrate Scope

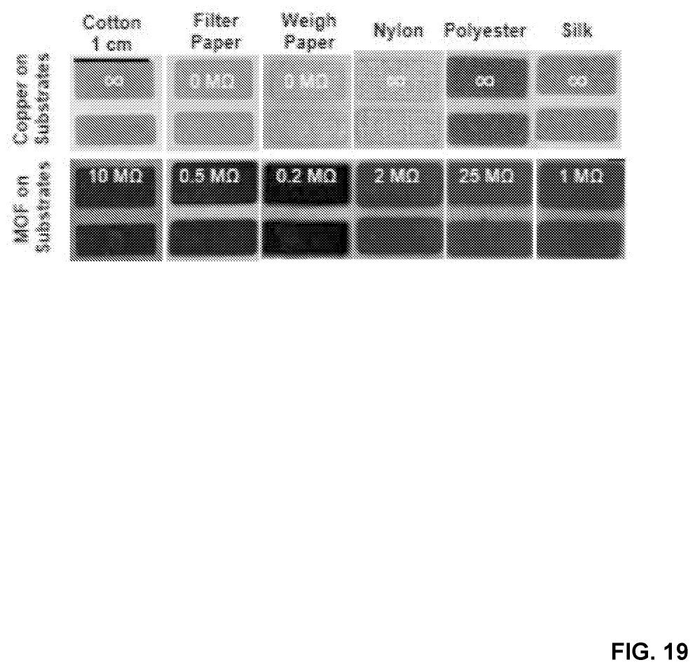

FIG. 19 illustrates patterned copper (120 nm) deposition on cotton, filter paper, weigh paper, nylon, polyester, and silk using a mask to form pre-patterned rectangles of varying dimensions (1 cm×0.5 cm, and 1 cm×0.4 cm) followed by oxidative restructuring to form Cu₃HHTP₂.

### Example 2.16. SEM Images of Cu and Cu₃HHTP₂ on Substrates

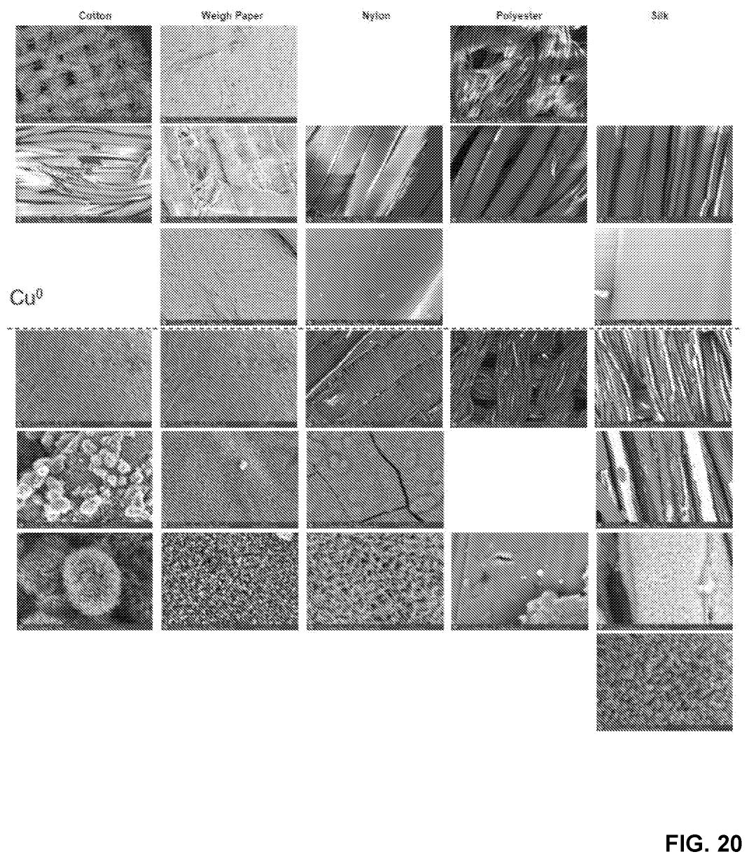

FIG. 20 illustrates SEM images of Cu and Cu₃HHTP₂ on substrates.

### Example 2.17. SEM Images of Cu on Cotton and CuHHTP on Cotton

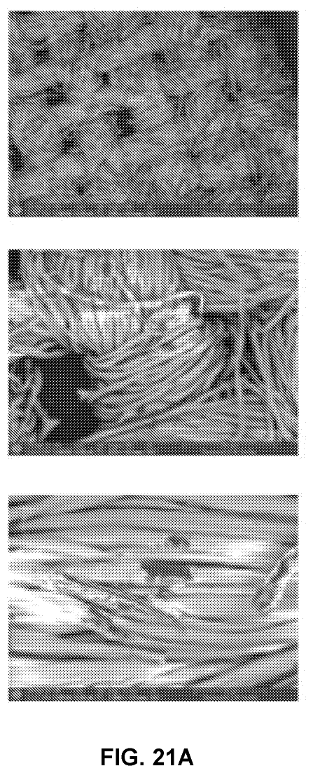

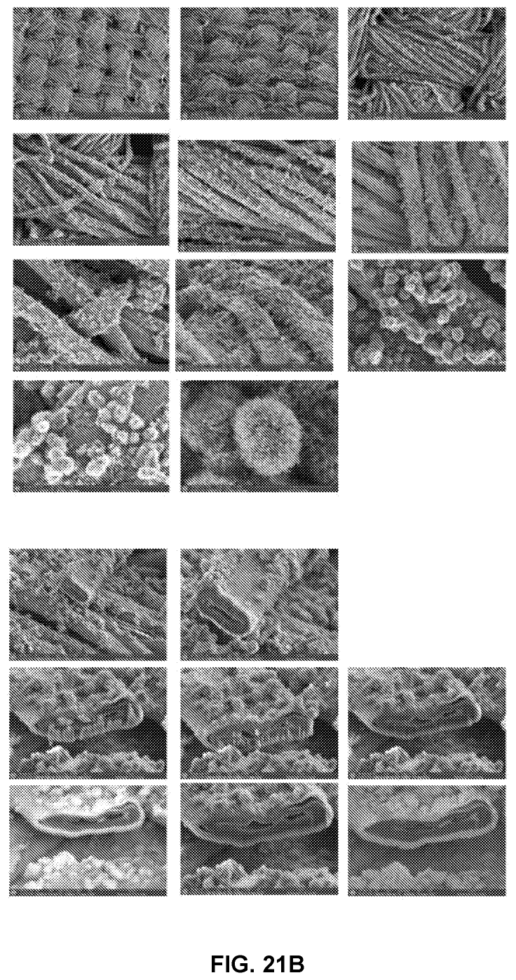

FIGS. 21A and 21B illustrate SEM images of Cu on cotton (FIG. 21A) and CuHHTP on cotton (FIG. 21B).

### Example 2.18. SEM Images of CuHHTP on Cotton after Washing and Sonification

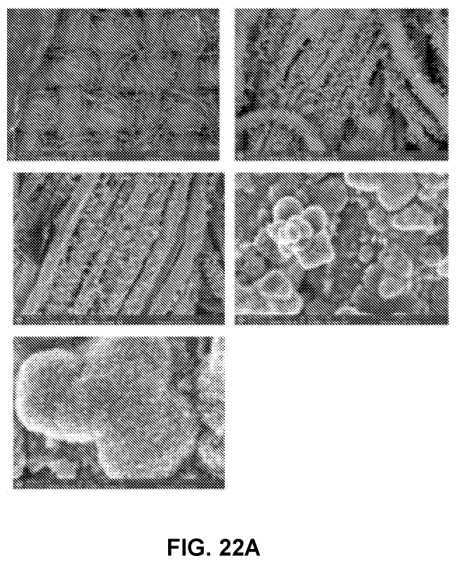

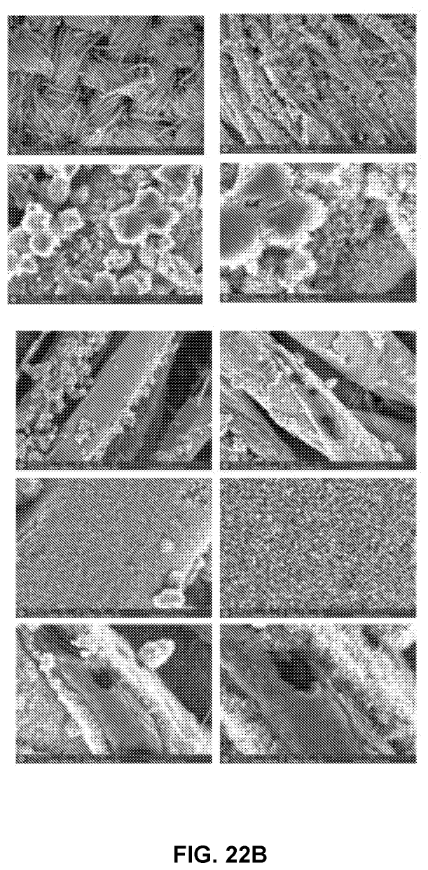

FIGS. 22A and 22B illustrate SEM images of CuHHTP on cotton after washing (FIG. 22A) and sonification (FIG. 22B).

### Example 2.19. SEM Images of Cu on Weighpaper and CuHHTP on Weighpaper

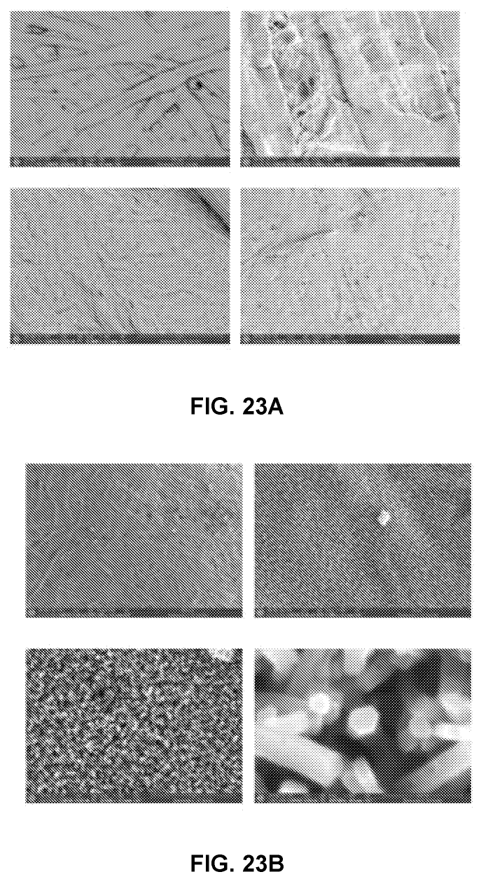

FIGS. 23A and 23B illustrate SEM images of Cu on weighpaper (FIG. 23A) and CuHHTP on weighpaper (FIG. 23B).

### Example 2.20. SEM Images of CuHHTP on Weighpaper after Washing and Sonification

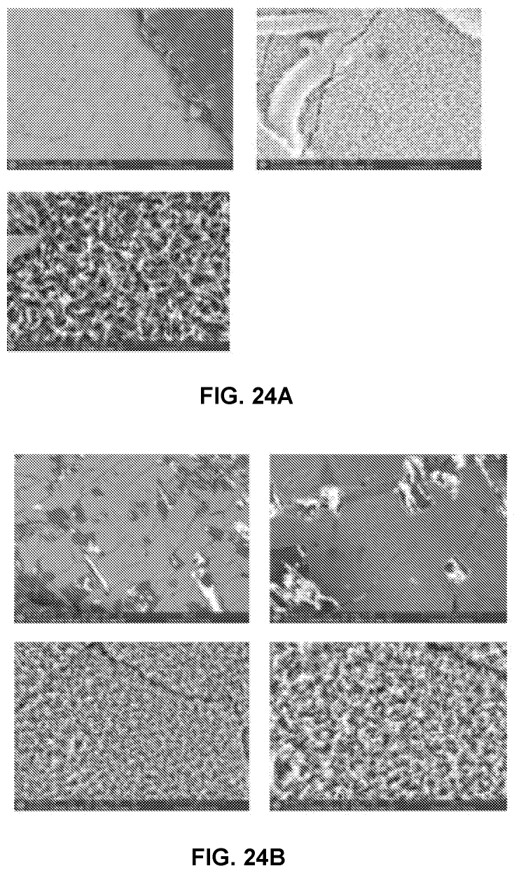

FIGS. 24A and 24B illustrate SEM images of CuHHTP on weighpaper after washing (FIG. 24A) and sonification (FIG. 24B).

### Example 2.21. SEM Images of Cu on Nylon and CuHHTP on Nylon

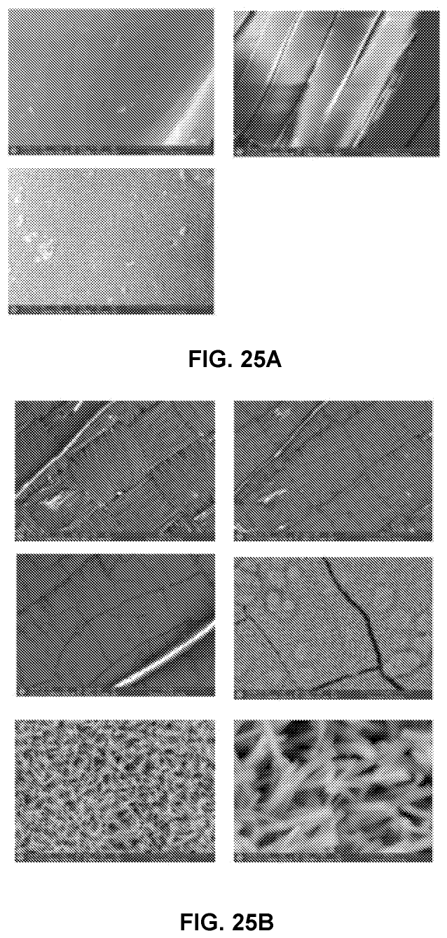

FIGS. 25A and 25B illustrate SEM images of Cu on nylon (FIG. 25A) and CuHHTP on nylon (FIG. 25B).

### Example 2.22. SEM Images of CuHHTP on Nylone after Washing and Sonification

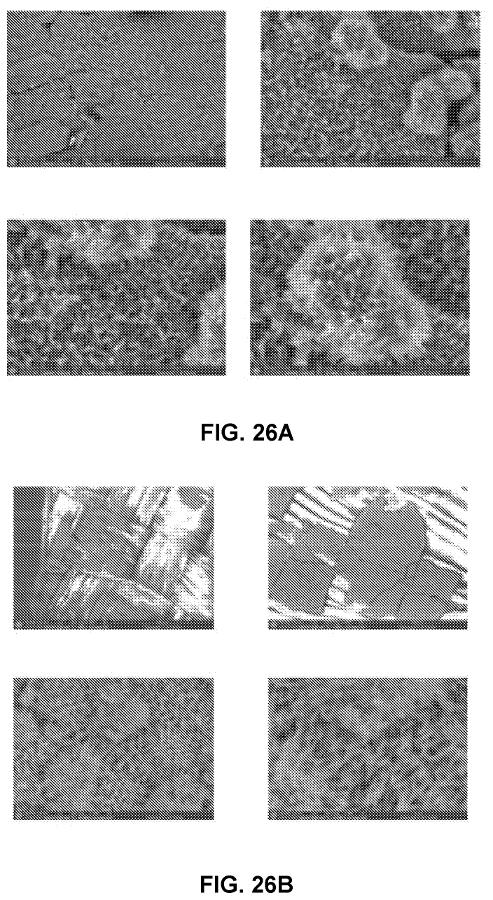

FIGS. 26A and 26B illustrate SEM images of CuHHTP on nylon after washing (FIG. 26A) and sonification (FIG. 26B).

### Example 2.23. SEM Images of Cu on Polyester and CuHHTP on Polyester

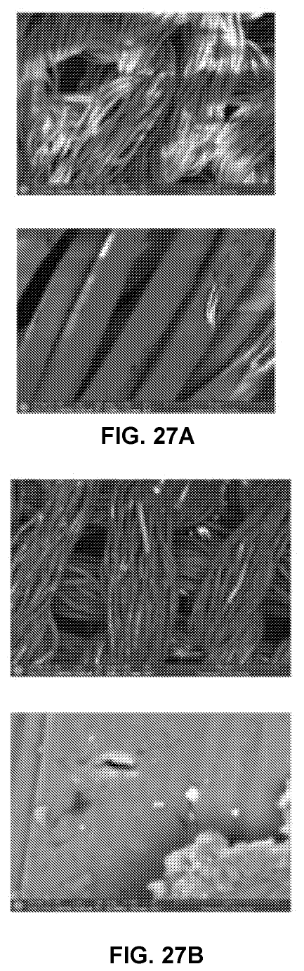

FIGS. 27A and 27B illustrate SEM images of Cu on polyester (FIG. 27A) and CuHHTP on polyester (FIG. 27B).

### Example 2.24. SEM Images of CuHHTP on Polyester after Washing and Sonification

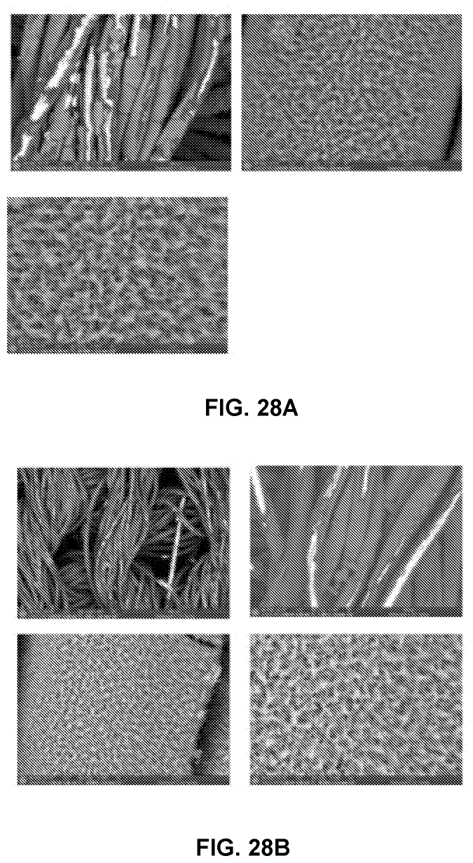

FIGS. 28A and 28B illustrate SEM images of CuHHTP on polyester after washing (FIG. 28A) and sonification (FIG. 28B).

### Example 2.25. SEM Images of Cu on Silk and CuHHTP on Silk

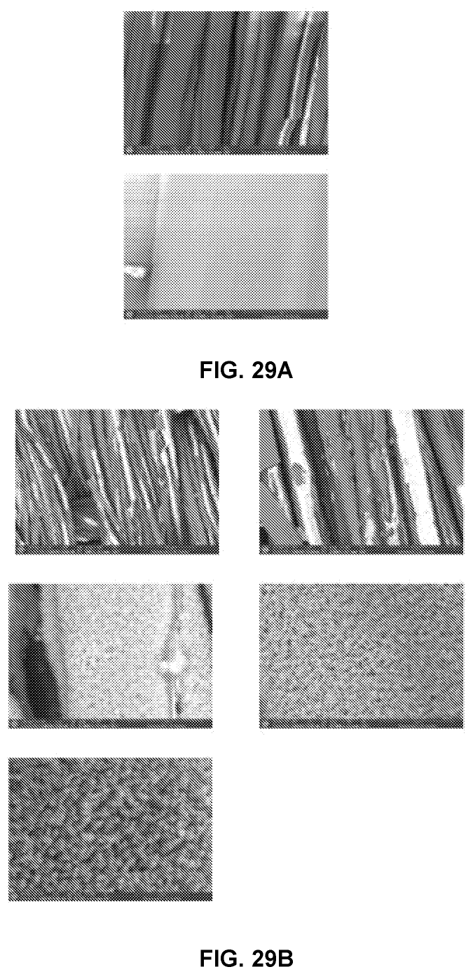

FIGS. 29A and 29B illustrate SEM images of Cu on silk (FIG. 29A) and CuHHTP on silk (FIG. 29B).

### Example 2.26. SEM Images of CuHHTP on Silk after Washing and Sonification

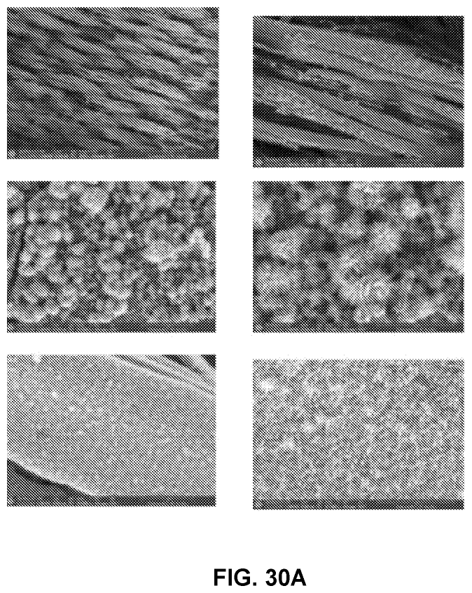

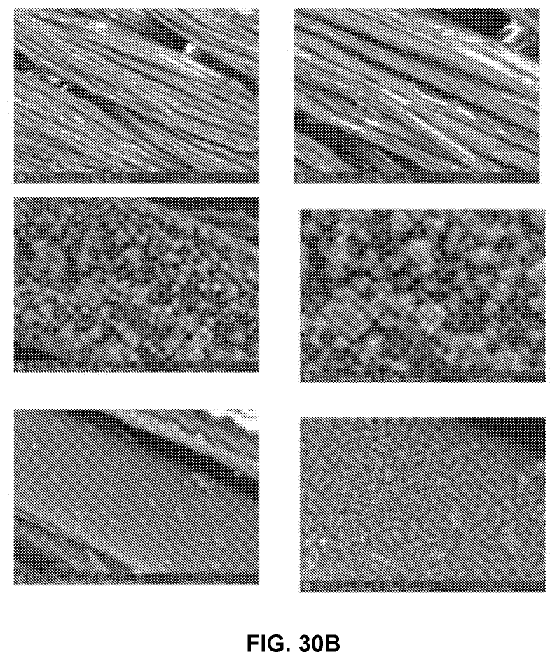

FIGS. 30A and 30B illustrate SEM images of CuHHTP on silk after washing (FIG. 30A) and sonification (FIG. 30B).

### Example 2.27. Sensing After Devices Heater at 130° C. for 96 Hours

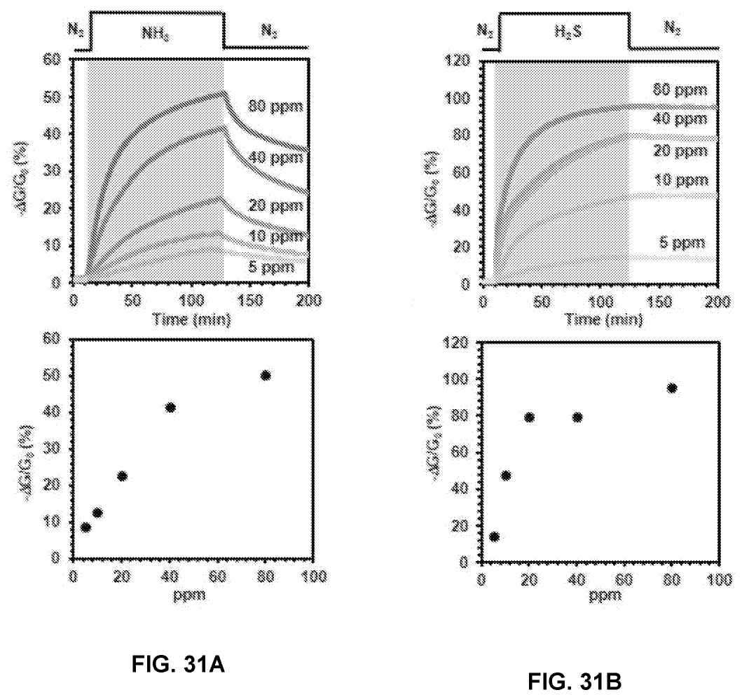

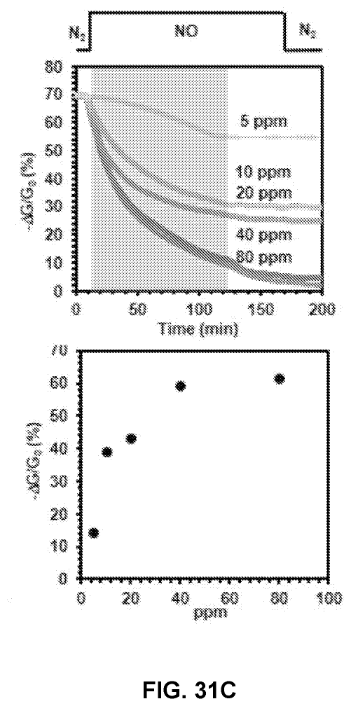

FIGS. 31A, 31B, and 31C illustrate sensing performance of Cu₃HHTP₂ on cotton as chemiresitors when exposed to gaseous analytes. Representative sensing traces show in the change in conductance −ΔG/G₀ (%) over time (min) exposed to three different gasses: NH₃ (FIG. 31A), NO (FIG. 31B), and H₂S (FIG. 31C) ranging from 5-80 ppm diluted with N₂ at room temperature. The grey region represents the duration of exposure to the analyte and the white region represents baseline and recovery in N₂. Concentration dependence plots of sensing response of the Cu₃HHTP₂ MOF on cotton to NH₃, NO, and H₂S (5-80 ppm).

### Example 2.28. Reusability of Washed Devices for Chemiresistive Sensing

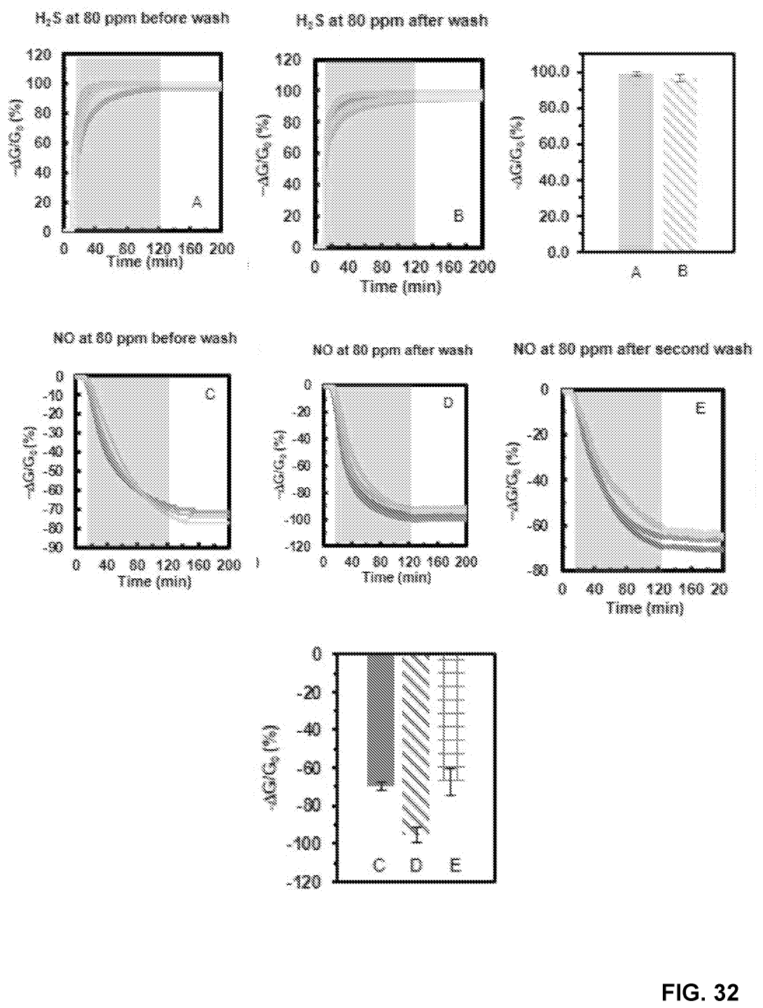

FIG. 32 illustrates reusability of washed devices for chemiresistive sensing.

Without further elaboration, it is believed that one skilled in the art can, using the description herein, utilize the present disclosure to its fullest extent. The embodiments described herein are to be construed as illustrative and not as constraining the remainder of the disclosure in any way whatsoever. While the embodiments have been shown and described, many variations and modifications thereof can be made by one skilled in the art without departing from the spirit and teachings of the invention. Accordingly, the scope of protection is not limited by the description set out above, but is only limited by the claims, including all equivalents of the subject matter of the claims. The disclosures of all patents, patent applications and publications cited herein are hereby incorporated herein by reference, to the extent that they provide procedural or other details consistent with and supplementary to those set forth herein.

What is claimed is:

1. A method of forming metal-organic frameworks, said method comprising:
exposing a plurality of zero-oxidation state metal atoms to an oxidizing agent,
wherein the exposing facilitates oxidation of the plurality of zero-oxidation state metal atoms to a plurality of metallic ions,
wherein the plurality of metallic ions react with a plurality of ligands to form the metal-organic frameworks, and
wherein the formed metal-organic frameworks comprise one or more metals and one or more ligands coordinated with the one or more metals.

2. (canceled)

3. The method of claim 1,
wherein the plurality of ligands are selected from the group consisting of organic ligands, amino acids, dipeptide linkers, glycine-serine dipeptide linkers, beta-alanine and L-histidine dipeptide linkers, 4,4′-bipyridine linkers, polydentate linkers, bidentate linkers, tridentate linkers, imidazole linkers, hexatopic ligands, polydentate functional groups, aromatic ligands, triphenylene-based ligands, triphenylene derivatives, hexahydroxytriphenylene-based organic linkers, hexaiminotriphenlyene-based organic linkers, tridentate ligands, thiol-containing ligands, tridentate thiol-containing ligand, bis(dithiolene), 2,3,6,7,10,11-hexahydroxytriphenylene (HHTP), 2,3,6,7,10,11-hexaaminotriphenylene (HITP), trimesic acid (1,3,5-benzenetricarboxylic acid, BTC), aspartic acid, 2,3,6,7,10,11-hexathiotriphenylene (HTTP), terephthalic acid (1,4-benzodicarboxylic acid), 4,4′-biphenyldicarboxylate (BPDC), p-terphenyl-4,4′-dicarboxylate, 1,3,5-tris(3′,5′-dicarboxy[1,1′-biphenyl]-4-yl)benzene, dppd(1,3-di(4-pyridyl)propane-1,3-dionato), 1,3,5-Tris(4-carboxyphenyl)benzene (BTB), or combinations thereof;
wherein the plurality of metallic ions are selected from the group consisting of Co²⁺, Ni²⁺, Cu²⁺, Cu⁺, Ag⁺, Fe²⁺, Zn²⁺, Zr⁺, Zr²⁺, Sc⁺, or combinations thereof;
wherein the plurality of zero-oxidation state metal atoms are selected from the group consisting of copper, cobalt, nickel, zinc, silver, iron, zirconium, scandium, a metal, a metalloid, a transition metal, a post-transition metal, a lanthanide, or combinations thereof;
wherein the oxidizing agent is selected from the group consisting of an oxygen-containing compound, O₂, H₂O₂, a halogen, atmospheric oxygen, or combinations thereof; and
wherein the metal-organic frameworks are two-dimensional or three-dimensional.

4. (canceled)

5. The method of claim 1, wherein the metal-organic frameworks are selected from the group consisting of Co₃HTTP₂, Ni₃HTTP₂, Cu₃HTTP₂, Co₃HHTP₂, Ni₃HHTP₂, Cu₃HHTP₂, Co₃HITP₂, Ni₃HITP₂, Cu₃HITP₂, CuBTC, or combinations thereof.

6-7. (canceled)

8. The method of claim 1, wherein the metal-organic frameworks are conductive.

9. (canceled)

10. The method of claim 1, wherein the exposing facilitates in situ formation of metallic ions, and wherein the in situ formation occurs by an oxidation method selected from the group consisting of air oxidation, steam oxidation, water oxidation, salt bath oxidation, or combinations thereof.

11. (canceled)

12. The method of claim 1, where the plurality of zero-oxidation state metal atoms undergo oxidation and provide nucleation sites for growth of the metal-organic frameworks.

13. The method of claim 1, wherein the exposing is performed by at least one of mixing, dipping, spraying, spin coating, thermal evaporation, vapor deposition, painting, drop casting, electroplating, electro-less plating, and combinations thereof; and
wherein the exposing is performed for a period of time sufficient for at least some of the plurality of zero-oxidation state metal atoms to undergo oxidation.

14-18. (canceled)

19. The method of claim 1, wherein the plurality of metallic ions exclude metal oxides, metal hydroxides, metal oxide intermediates, metal hydroxide intermediates, or combinations thereof.

20-21. (canceled)

22. The method of claim 1, further comprising a step of associating the plurality of zero-oxidation state metal atoms with a surface.

23. The method of claim 22, wherein the associating is performed by at least one of mixing, dipping, spraying, spin coating, thermal evaporation, vapor deposition, painting, drop casting, electroplating, electro-less plating, patterning, or combinations thereof.

24. The method of claim 22, wherein the associating occurs before the exposing step.

25. The method of claim 22, wherein the associating occurs by patterning.

26. The method of claim 25, wherein the patterning forms a geometric pattern of the zero-oxidation state metal atoms on the surface, and wherein the geometric pattern is selected from the group consisting of polygons, triangles, squares, rectangles, pentagons, ridges, protrusions, or combinations thereof.

27. (canceled)

28. The method of claim 25, wherein the patterning step and the exposing step result in the patterned growth of the metal-organic frameworks on the surface.

29. The method of claim 22, wherein the surface is selected from the group consisting of textiles, cotton, nylon, glass, functionalized glass, paper, silica, mica, natural polymers, synthetic polymers, non-crystalline amorphous solids, carbon-based materials, carbon fibers, porous materials, flexible materials, or combinations thereof.

30. The method of claim 22, wherein the surface is glass.

31. The method of claim 22, wherein the surface is functionalized with a functional group to provide an anchor for the plurality of metallic ions formed by the plurality of zero-oxidation state metal atoms.

32. The method of claim 31, wherein the functional group is a hydroxyl group.

33. The method of claim 1, further comprising a step of contacting the plurality of zero-oxidation state metal atoms with the plurality of ligands, and wherein the contacting step occurs before, during, or after the exposing step.

34. The method of claim 33, wherein the contacting step occurs before the exposing step.

35-36. (canceled)
